(19) United States
(12) Patent Application Publication
(10) Pub. No.: US 2013/0337601 A1
(43) Pub. Date: Dec. 19, 2013

(54) STRUCTURES AND METHODS FOR HIGH EFFICIENCY COMPOUND SEMICONDUCTOR SOLAR CELLS

(71) Applicant: Solexel, Inc., (US)

(72) Inventors: Pawan Kapur, Palo Alto, CA (US); Mehrdad M. Moslehi, Los Altos, CA (US)

(21) Appl. No.: 13/781,708

(22) Filed: Feb. 28, 2013

Related U.S. Application Data
(60) Provisional application No. 61/605,186, filed on Feb. 29, 2012.

(51) Int. Cl. H01L 31/18

(52) U.S. Cl. CPC H01L 31/184
USPC 438/93

(57) ABSTRACT

Methods and structures are provided for the growth and separation of a relatively thin layer crystalline compound semiconductor material containing III-V device layers, including but not limited to Gallium Arsenide (GaAs), on top of a crystalline silicon template wafer. Solar cell structures and manufacturing methods based on the crystalline compound semiconductor material are described.

### CROSS-REFERENCE TO RELATED APPLICATIONS

This application claims the benefit and priority of U.S. Provisional Patent App. No. 61/605,186 filed on Feb. 29, 2012, which is hereby incorporated by reference in its entirety.

### FIELD OF THE INVENTION

The present disclosure relates in general to the field of photovoltaics, and more particularly to high-efficiency compound semiconductor solar cells.

### BACKGROUND

One of the current challenges for mass-scale world-wide deployment of photovoltaic (PV) systems is the reduction of the levelized cost of electricity (LCOE) for the electricity generated from PV systems below that of conventional fossil fuels, without reliance on subsidies and regulatory support. Reduction of LCOE may comprise reducing the cost of solar cell and module fabrication while increasing the efficiency of the fabricated solar cells and modules, as well as reduction of the installed PV system balance-of-system (BOS) costs (part of the BOS cost is scaled down with increasing the PV module efficiency). For example, the low-cost production of high efficiency solar cells with efficiencies beyond that of crystalline Si (25% in practice), formed using materials such as mono-crystallin direct bandgap materials, such as Gallium Arsenide (GaAs), can enable very attractive and competitive LCOE for such installed PV systems. In some instances, direct bandgap materials, such as GaAs, require little or minimal absorber thickness (for example as little as about 1 micron to several microns) to absorb sunlight efficiently (with very high quantum efficiency). Reduced material thickness may significantly reduce material and processing costs while enabling high efficiency solar cells and low-cost manufacturing. Further, materials having a larger semiconductor bandgap energy, for instance, bandgap energy on the order of 1.4 eV (such as monocrystalline GaAs) usually provide higher open circuit voltage (Voc) as compared to silicon (Si), which will enable higher cell and module conversion efficiencies as well as providing a lower temperature coefficient of efficiency (less efficiency degradation at higher cell temperatures in the fiel)—thus in some instances enabling substantially enhanced energy yield and an further reduction in LCOE.

However, currently direct band gap materials, such as mono-crystalline direct gap band materials (for example group III-V materials) and particularly GaAs), have not been fully realized in mass-scale and broad commercial implementations (including for residential and commercial rooftops). In a traditional and common solar cell materials and manufacturing implementation, an expensive bulk GaAs wafer (typically with a wafer thickness in the range of about 200 to several hundred microns) is processed to make a solar cell. While light absorption is performed only in the first micron or few microns of the direct-bandgap absorber, most (e.g., greater than 95%) of the remaining thickness of the wafer is used to mechanically support the actively absorbing top few microns of light absorption GaAs during device fabrication process. Thus, it may be considered highly inefficient to use an expensive material such as a GaAs wafer for mechanical support. In most cases, the active solar cell absorber layer stack (for a single junction or multi-junction solar cell) is actually deposited by a metal-organic chemical-vapor deposition (MOCVD) process on the GaAs substrate; in these cases, essentially 100% of the GaAs wafer is used for mechanical support (and also for epitaxial growth of the solar cell absorber layer or stack of layers by MOCVD). In a second and alternative GaAs solar cell implementation, attempts have been made to address the high cost of expensive GaAs wafer for use as a mechanical support (and also as epitaxial growth substrate for the growth of the compound semiconductor absorber layer by MOCVD). These methods may reuse the expensive GaAs wafer as a reusable template, hence, amortizing the cost of the starting GaAs wafer over multiple reuse cycles. However, since GaAs wafers are very expensive (and also far more limited in size compared to silicon wafers), in most instances the GaAs wafer used as a reusable template has to be reused at least hundreds of times with extremely high (e.g., 99.9% or more) yield without breakage in order to reduce the resulting solar cell costs significantly and make them competitive compared to the mainstream traditional silicon solar cell technologies (in terms of cell cost per watt). This poses significant technological and manufacturing challenges for commercial viability of GaAs wafer as a reusable template for cost-effective photovoltaics. Furthermore and importantly, this method is practically limited to the production of a smaller sized GaAs solar cell size (for instance, up to 100 mm×100 mm or at most 125 mm×125 mm) because of prohibitively expensive cost of GaAs wafers as well as the technological difficulties and economic challenges of producing and processing large area GaAs wafers (for instance, 200-mm in diameter or 156 mm×156 mm cell dimensions) on which the GaAs solar cell is formed and processed.

While high efficiency, single-junction and multi-junction cells have been made and demonstrated using III-V materials such as GaAs in the past, these structures and manufacturing processes have been plagued and limited by the very high cost of the starting wafer which has prevented their widespread penetration into the mainstream terrestrial PV market (excluding the CPV market segment for certain ground-mount utility applications in high DNI solar radiation regions). It is well known that the cost of GaAs wafers is significantly higher than that of silicon wafers, while the largest economically viable GaAs wafers are substantially smaller than the corresponding silicon wafers. GaAs wafers are commonly made in smaller sizes as compared to silicon (GaAs wafers are formed currently up to about 150-mm in diameter as compared to up to 300-mm diameter or even 450-mm diameter for Si wafers) and are substantially more brittle and mechanically much weaker than silicon. Historically, a GaAs cell fabrication process may start with a semiconductor substrate such as Germanium (Ge) or GaAs and build GaAs based solar cells on top of these very expensive substrates (it is be noted Ge wafers are also very expensive as compared to Si wafers). For example, a single junction GaAs solar cell formation process may entail growing both n-type and p-type doped GaAs material layers along with the so-called widegap window layers and back surface field (BSF), for instance using AlGaAs (a semiconductor with wider bandgap than GaAs—see FIG. 2 for a bandgap vs lattice constant graph). This is followed by metal contacts formation and an anti reflection coating (ARC) layer. However, there are several problems with this conventional III-V compound semiconductor material based solar cell and fabrication process, particularly relating to cost and scalability:
The starting substrates (such as GaAs or Ge wafers) are relatively expensive and substantially more expensive as compared to Si.
The starting substrates/wafers are typically smaller, in the range of approximately 75 mm up up to 150 mm in diameter, and substantially smaller as compared to prevalent Si substrates/wafers which are routinely 200 mm to 300 mm in diameter (prototypes of 450 mm diameter CZ silicon wafers have been demonstrated as well) and 156 mm×156 mm squares (or 210 mm×210 mm squares) for solar cells. In order to make them relatively cost-effective for certain ground-mount utility applications, small area compound semiconductor solar cells are almost exclusively used in very high-concentration PV (CPV) applications, often requiring expensive and large concentrators and multi-axis trackers (and in some cases liquid cooling of the solar cells).
Conventional III-V semiconductor based solar cells often use and rely on unconventional and expensive cell packaging schemes which do not have the economies of scale as silicon based PV modules (particularly for applications without concentrators).
Despite a higher cell efficiency, of the primary issues with compound semiconductor solar cells and modules relate to the very high cost of the starting material (GaAs or Ge wafers), manufacturing methods (such as relatively low-throughput MOCVD systems), and additional cost of Balance of Systems (BOS) of compound semiconductor CPV systems, including concentrators and trackers (and cooling systems). These issues make the overall system level cost ($/Watt) metric relatively high. Due to mechanical components in the BOS (multi-axis trackers), these systems can have lower field reliability and more maintenance requirements.

A partial improvement over the above described III-V semiconductor structures and fabrication methods entails growing a thin (about 1 micron up to a few microns of absorber) GaAs solar cell absorber stack (as only a thin absorber layer is required to efficiently absorb sunlight) on top of a relatively thick (e.g., a few hundred microns thick for good mechanical support and to enable high-yield solar cell fabrication) GaAs or germanium wafer and reusing the GaAs (or Ge) substrate for additional thin GaAs solar cell absorber formation cycles to amortize and mitigate the cost of the GaAs (or germanium) substrate/wafer. Often, GaAs solar cell absorber stack growth is performed using Molecular Beam Epitaxy (MBE) or Metal-Organic Chemical-Vapor Deposition (MOCVD), and the resulting thin GaAs-based absorber layer (or layer stack comprising layers such as GaAs, AlGaAs, etc.) serves as the high-efficiency solar cell absorber. Although, this may represent an economic (cost reduction) improvement to the previous III-V semiconductor solar cell manufacturing schemes, this approach may also suffer from serious manufacturing challenges (such as the limited reuse number of the extremely brittle, fragile, and expensive GaAs wafers) relating to manufacturing cost and scalability for widespread terrestrial mass deployment and adoption, particularly in the market segments where crystalline silicon PV is dominant (for instance the residential and commercial rooftop markets in particular, as well as even the ground mount utility scale PV installations). For example:
Because of the high cost of the GaAs (and Ge) wafers, the GaAs (or Ge) wafer will have to be reused at least several hundred times without any breakage and without any degradation of the surface quality in order to ensure that the amortized starting wafer cost is not a significant contributor to the overall cost of the resulting III-V solar cells and modules.
Since GaAs is intrinsically a brittle and fragile semiconductor material, reuse yield of this material for several hundred times without breakage is extremely challenging and difficult. In practice, the maximum number of reuses for a GaAs wafer has been shown to be about 5 (maybe extended up to tens of reuse cycles in practice as the number of reuses is limited by breakage and/or degradation of the GaAs wafer). Hence, there is a large reuse performance gap between what has been shown or can be demonstrated (10's of cycles at maximum) and what's required (at least 100's of cycles) to achieve the desired manufacturing cost targets.
The size of the solar cell is limited by the size of the widely available starting GaAs wafers, resulting in low power output per cell despite relatively high cell efficiency. Current available GaAs wafer size is in the range of up to about 150 mm diameter (compared to much larger size of Silicon substrates: 200 mm to 300 mm in diameter), making the largest practical solar cell sizes about 100 mm×100 mm full square or about 125 mm×125 mm pseudo square.
Handling of the thin (typically <5 microns) GaAs solar cell absorber stack layer after it is detached from the carrier GaAs wafer can be quite challenging and costly depending on the scheme deployed. Furthermore, GaAs is a very brittle and fragile material and problems relating to GaAs substrate processing yield and structural integrity are substantially compounded as the substrate size (area) increases. Thus the GaAs absorber should be supported by a reliable carrier during processing after detachment. As is described below, the embodiments of disclosed herein effectively overcome such problems and constraints, enabling low-cost and high-yield fabrication of large-area GaAs-based single-junction and multi-junction solar cells.
Mass commercialization of known schemes may be substantially restricted by manufacturing equipment limitations. For example, cost effective high volume MOCVD reactors are not yet commercially available for mass scale solar cell manufacturing. The commercially available MOCVD and MBE tools have relatively small batch sizes and result in very low production throughputs, typically on the order of a few to 10's of wafers per hour. Low-cost solar cell manufacturing tools must have throughputs at least 1 to 2 orders of magnitude larger than the currently available commercial MOCVD and MBE tools. The fabrication requirement may be least 100's of wafers per hour per tool for MOCVD or MBE processing of the solar cells.

### BRIEF SUMMARY OF THE INVENTION

Therefore, a need has arisen for device layer fabrication for high-efficiency compound semiconductor solar cells from a relatively inexpensive crystalline silicon template wafer. In accordance with the disclosed subject matter, structures and methods for fabricating a photovoltaic solar cell are disclosed which substantially eliminate or reduce the cost and scaling disadvantages associated with previously developed compound semiconductor solar cell fabrication methods.

According to one aspect of the disclosed subject matter, a method is provided for the growth and separation of a relatively thin (from less than about 1 micron up to several microns) layer of desired thickness of crystalline compound semiconductor material containing III-V device layers including but not limited to Gallium Arsenide (GaAs), on top of a much thicker, strong, and relatively inexpensive crystalline silicon template wafer. If desired, such crystalline silicon template wafer may be reused to produce a plurality of compound semiconductor solar cells, hence, reducing the amortized cost of the inexpensive crystalline silicon template per solar cell produced.

These and other aspects of the disclosed subject matter, as well as additional novel features, will be apparent from the description provided herein. The intent of this summary is not to be a comprehensive description of the claimed subject matter, but rather to provide a short overview of some of the subject matter's functionality. Other systems, methods, features and advantages here provided will become apparent to one with skill in the art upon examination of the following FIGUREs and detailed description. It is intended that all such additional systems, methods, features and advantages that are included within this description, be within the scope of any claims.

### BRIEF DESCRIPTION OF THE DRAWINGS

The features, natures, and advantages of the disclosed subject matter may become more apparent from the detailed description set forth below when taken in conjunction with the drawings in which like reference numerals indicate like features and wherein:

FIG. 1 showing comparing the costs of starting wafers;

FIG. 2 is a graph showing energy bandgap vs. lattice constant for various direct and indirect bandgap semiconductors;

FIG. 3 are cross sectional diagrams showing the growth sequence for large area GaAs layers on Si substrates;

FIG. 4 depicts the process for growing large area GaAs layers on top of Silicon using porous silicon and Germanium;

FIG. 5 is a cross-sectional diagram showing a standard single junction front-contact GaAs solar cell on a bulk GaAs substrate;

FIG. 6 is a cross-sectional cell diagram of showing a thin GaAs based single junction front contact cell;

FIG. 7 are cross-sectional diagrams showing the formation of a single junction GaAs based cell by directly growing Ge on porous silicon;

FIG. 8 is a scanning electron microscopic (SEM) picture showing a single crystal Germanium grown directly on porous silicon;

FIG. 9 is a graph showing the maximum achievable efficiency as a function of the choice of the bandgap of top and bottom materials in a two-junction tandem cell; and

FIG. 10 is a cross-sectional graph showing a typical multi-junction cell which may be fabricated in accordance with the disclosed subject matter.

### DETAILED DESCRIPTION

The following description is not to be taken in a limiting sense, but is made for the purpose of describing the general principles of the present disclosure. The scope of the present disclosure should be determined with reference to the claims. Exemplary embodiments of the present disclosure are illustrated in the drawings, like numbers being used to refer to like and corresponding parts of the various drawings.

And although the present disclosure is described with reference to specific embodiments, such compound semiconductor solar cells using gallium arsenide absorber and other described fabrication materials on crystalline silicon template wafers, one skilled in the art could apply the principles discussed herein to alternative cell structures (including various cell structures with front-contact and/or back-contact designs, single-junction and multi-junction solar cells, etc.) and other fabrication materials including alternative elemental and compound semiconductor materials (such as germanium, gallium nitride, etc.), technical areas, and/or embodiments without undue experimentation. Moreover, while the representative embodiments show fabrication of compound semiconductor (such as absorbers comprising GaAs) solar cells on one side or face of the crystalline silicon template, it should be understood that such solar cells may be fabricated on both sides or faces of the crystalline silicon template wafers (by forming the sacrificial porous silicon seed and release layers on both sides of the silicon templates), hence, further increasing the effective productivity and further reducing the manufacturing cost of the resulting solar cells and modules.

The disclosed subject matter overcomes shortcomings relating to III-V compound semiconductor substrate formation and provides cost-effective manufacturing methods high-efficiency compound semiconductor solar cells using crystalline silicon templates. Such crystalline silicon templates may be used to make one compound semiconductor solar cell per crystalline silicon template or a plurality of compound semiconductor solar cells for each crystalline silicon template, the latter through multiple reuses of such templates (hence, further amortizing the cost of the crystalline silicon template over the reuse cycles and reducing the effective template cost per solar cell). Compared to previous GaAs or III-V or other compound semiconductor wafer-based solar cells, the disclosed fabrication methods and structures dramatically lower the solar cell manufacturing costs also enabling fabrication of solar cells with larger areas, while providing the full benefits of high efficiency and larger energy yield advantages of direct bandgap based solar cells made with materials such as GaAs. As compared with conventional crystalline Si solar cells, the disclosed fabrication methods and structures may provide higher efficiencies while further reducing cost per watt.

Embodiments and aspects of the disclosed subject matter generally include, among others:
Methods for manufacturing large area (for example 125 mm×125 mm or or 156 mm×156 mm or 210 mm×210 mm, or even greater sizes and areas) very thin (for instance, from about 0.1 μm to about 10 μm) compound semiconductor solar cell structures (such as substantially single crystal direct bandgap III-V semiconductors including but not limited to GaAs) in a very cost-effective manner, in which the template cost (including the mechanical handling of the thin substrates) used to enable high-yield manufacturing of these thin compound semiconductor solar cells is dramatically reduced based on the use of porous silicon seed/release layer on top of a crystalline silicon template.
Structures and architectures of high efficiency III-V (particularly using single-junction and multi-junction abrorbers comprising GaAs and/or its ternary alloys) based solar cells compatible with the aforementioned low cost, large area substrates.
Methods for manufacturing high-efficiency single-junction and multi-junction solar cell designs based on growth on rather inexpensive crystalline silicon templates.

Decoupling of the solar cell absorber (active part of the resulting solar cell) function from the function of mechanical support (as well as epitaxial seeding) of the absorber provides for the manufacture of cost effective large area III-V (such as GaAs) based solar cells, suitable for cost-effective mass scaling. Decoupling allows for targeting and using cost effective and efficient materials, which are generally dissimilar (for example, high-performance direct-bandgap thin III-V semiconductor layer for solar cell absorber and a very cost effective and strong elemental semiconductor material, particularly such as Si, for mechanical support and epitaxial seeding of the absorber through the use of an appropriate intermediate buffer layer to accommodate any lattice mismatch between silicon and the compound semiconductor layer or layer stack) to provide the function of solar cell absorber as well as the functions of mechanical structure support and epitaxial seeding. For example, in order to achieve the lowest manufacturing cost, the thin compound semiconductor (such as the single-junction or multi-junction absorber layer comprising GaAs and/or its ternary alloys) material is used only as a thin but sufficient solar absorber (for example with a thickness in the range of about 0.5 micron up to about 10 microns), while an inexpensive crystalline silicon wafer (without any stringent material quality such as minority carrier lifetime requirements) is used to enable epitaxial seeding and growth of the thin compound semiconductor absorber and mechanically support of the thin compound semiconductor absorber during at least a portion or during essentially entire solar cell manufacturing process flow. This schemes of this invention using the inexpensive crystalline silicon template and sacrificial porous silicon seed/release layer represent a substantial advancement and significant manufacturing cost reduction over the known and state of the art methods for III-V compound semiconductor solar cell production, where the functions of absorbing (either directly or through growth of the epitaxial compound semiconductor absorber layer structure on top of the expensive wafer) and mechanical support are performed by rather expensive semiconductor materials, using either GaAs or Ge as starting wafers. As mechanical support requires a relatively thick (for instance, several hundred microns thick) wafer used as the thin absorber support, known prior art methods using III-V semiconductor materials are often prohibitively expensive for mainstream PV applications (such as including residential and commercial rooftops besides the ground-mount utility scale PV applications).

Decoupling the functional responsibilities of light absorption and mechanical support (as well as epitaxial seeding of absorber structures formed by epitaxial deposition processes) by using dissimilar materials, based on the use of rather inexpensive and much lower cost crystalline silicon templates, disrupts the common conventional paradigms while providing a highly cost effective solution, retaining and providing the high efficiency advantages of the single-junction and multi-junction solar cells made using the III-V (GaAs) and related compound semiconductor materials. However, there are significant processing and structural challenges to overcome which may be facilitated by the following:
A method for growing a substantially monocrystalline or virtually single crystal, direct band gap based (for example, but not limited to, a single junction GaAs based, or a multi-junction III-V compound semiconductor based), large area (for example 125 mm×125 mm, 156 mm×156 mm, or larger) solar cell on a crystalline silicon wafer used as a template, wherein such template may be used once or multiple times through reuse cycles. In one embodiment, the manufacturing process of this invention uses porous silicon, formed on the crystalline silicon template, as a layer aiding both epitaxial seeding of an intermediate buffer layer comprising germanium as well as the separation between the crystalline Si template (also serving as a robust carrier) and the high efficiency solar cell substrate/absorber (along with any intermediate layer(s) such as Ge or a combination of silicon and germanium in a SiGe alloy). The intermediate crystalline layer(s) on porous silicon facilitates growth of high quality single crystal high efficiency compound semiconductor solar absorber (such as including GaAs). Since large area, commercially available, inexpensive crystalline silicon wafers are used as detachable carriers, the starting wafer cost is substantially reduced compared to known technologies using either GaAs or Ge wafers.
A silicon based template, for example with a sacrificial porous silicon seed and release layer, may be used as a mechanical support during partial or complete processing of the solar cell, made of different material than Si, (and used for epitaxial seeding of the subsequent intermediate buffer layer and compound semiconductor layer) while the solar absorber is still on/attached to the crystalline silicon template. For example, specific examples of on-template solar cell processing may include, but are not limited to, deposition of other films suitable for forming a back surface reflector and/or the widegap window layer and/or the back-surface contact metallization. Importantly, these layers may be deposited before or after the active solar cell absorber layer (for single junction or multi-junction solar cells), and may be formed in addition to the deposition of aforementioned intermediate buffer layers when intermediate buffer layers used.
In some instances, it may be desired that the crystalline silicon template is used for only one solar cell formation (in other words, reuse of the silicon template is not required to achieve cost benefits). This case without the crystalline silicon template reuse may be desirable in certain applications, such as for multi-junction solar cells with higher efficiencies, as it eliminates any challenges and residual costs related to reusing the silicon template (reconditioning and cleaning of the crystalline silicon template for the reuse cycles) while providing substantial cost advantages over conventional bulk GaAs substrate or even reusable GaAs template technology. Thus, this approach represents an intermediate cost benefit method achieving the cost reduction advantages relating to using a relatively inexpensive crystalline silicon template as compared to an expensive GaAs wafer and conventional direct bandgap III-V solar cell technology, while keeping processing complexity low. On the other hand, some embodiments disclosed herein, including both the single-junction and multi-junction solar cells, may still benefit from further manufacturing cost reduction through the reuse of the crystalline silicon template. However, the primary additional cost advantages and savings are achieved through a relatively modest number of reuse cycles (for instance from about 5 up to 10's of reuse cycles). Due to the relatively inexpensive crystalline silicon template, there is no need to drive towards higher numbers of reuse cycles. Moreover, crystalline silicon is much stronger, much less fragile, and much more robust than GaAs wafers, making their reuse far more practical than reuse of GaAs wafers. For instance, a 156 mm×156 mm crystalline silicon template costing US$2 and reused 10 times (to make 10 compound semiconductor solar cells from one template) will have an amortized template cost per solar cell of US$0.20. In contrast, a 156 mm×156 mm crystalline GaAs template costing $100 and reuse 10 times will have an amortized template cost per solar cell of US$10 or 50 times larger than that of the crystalline silicon template. In this example, the much weaker and more brittle GaAs template must be reuse 500 times in order to achieve the amortized template cost of the crystalline silicon template reused 10 times. This shows the tremendous cost and manufacturing yield/scaling advantages of the embodiments of this invention using crystalline silicon templates, with or without reuse of the template.
High volume and cost effective reactors for growing single junction GaAs on a silicon based starting template with intermediate layers. For example, a high volume epitaxial growth reactor such as high-volume batch atmospheric-pressure or reduced pressure epitaxial deposition reactor architecture. For solar cells based on materials other than GaAs and/or for GaAs based single and multi-junction solar cells, the structures and methods disclosed herein may utilize commercially available MOCVD or MBE reactors (or other similar commercially available reactors). Additionally, the disclosed subject matter implicitly includes, and does not preclude, using commercial reactors (such as MOCVD or MBE based) for GaAs based single junction cells as well. Rather, high volume epitaxial growth reactors are provided and may be desirable for use dependent on other considerations.
Detachment/release/separation methods for thin, large area (single crystal) compound semiconductor based (for example, solar cells with absorbers including GaAs and its ternary alloys) solar cell absorber layer (along with any intermediate layers and other relevant deposited layers) from a crystalline silicon template/wafer for completing the solar cell (for example detachment/separation at the porous silicon interface in some instances) with high yield and repeatability.
After detachment/separation of the thin, large area (single crystal) compound semiconductor based partially processed solar cell (for example GaAs), along with its constituent solar cell components and intermediate layers where applicable, from the silicon carrier at the porous silicon interface it may require mechanical and structural support to prevent breakage and yield losses. Structures and methods are provided for handling and supporting this fragile layer through remaining cell fabrication processes with high yield/robustness and at a very low cost, including attachment of a support handler immediately before or after semiconductor substrate detachment, with such support handler serving as a permanent support layer for the detached solar cell.

Cell structures and architectures (single and multi-junction cells) are provided. The cell structures are compatible with the disclosed thin GaAs substrate manufacturing methods, and may be integrated with the cost effective III-V semiconductor solar cell substrate manufacturing methods provided. For both single junction and multi-junction solar cells, front contact solar cells (having metallization/a metal grid on the cell frontside/sunnyside) and back contact solar cells (having metallization/a metal grid for both electrical polarities on the cell backside/non-sunnyside, hence minimizing shading losses and facilitating module-level interconnections of the resulting solar cells) may be formed in accordance with the embodiments described herein. Further, the schemes of emitter wrap through (EWT) or Metallization Wrap-Through (MWT) may be utilized in the case of back contacted III-V cells on the crystalline silicon template embodiments of described herein which have an additional advantage of removing reflected light from the metal grid and increasing effective light coupling into the solar cell.

Further, cell manufacturing methods, single junction and multi-junction front contact and back contact solar cells are provided along with representative process flows.

The exemplary embodiments described herein use low cost (as compared to making solar cells on GaAs and Ge wafers) crystalline Si wafers (far lower cost than GaAs or Ge wafers) with a thickness varying from 150 um to 1.5 mm (which may be dependent on whether the Si wafer to be reused) as a carrier and epitaxial seed for epitaxial growth and partial cell processing of thin GaAs-based and/or other direct bandgap monocrystalline compound semiconductor solar cells. The already much lower cost of the crystalline silicon wafers used as templates may be further lowered on a per cell basis by reusing each template for multiple (for instance, at least 2 and up to 10's) solar cell fabrication—resulting in a lower amortized template cost per cell as the number of reuse cycles increases). As Si wafers are much less brittle, much stronger, much more stable during thermal processing, and much less expensive as compared to other compound semiconductor (e.g., GaAs) materials (also much lower cost compared Ge), it is far easier and less costly to reuse silicon wafers and the number of reuses required to bring the cost down to a negligible fraction of the actual solar cells is far smaller than that of compound semiconductor (for example GaAs) or Ge wafers and carriers. However, the cost reductions already provided by using the crystalline Si wafer for one solar cell process, in other words no Si template wafer reuse, by growing the thin GaAs or other III-V compound semiconductor based solar cells on the inexpensive Si wafer template already substantially reduces the fabrication cost as compared to the conventional approaches using either the far more expensive GaAs (or Ge) wafer or even reused GaAs (or Ge) wafer (GaAs wafers are limited in practice to less than about 30-50 reuses in part due the brittleness and mechanical weakness of GaAs) for growing and carrying the absorber layer.

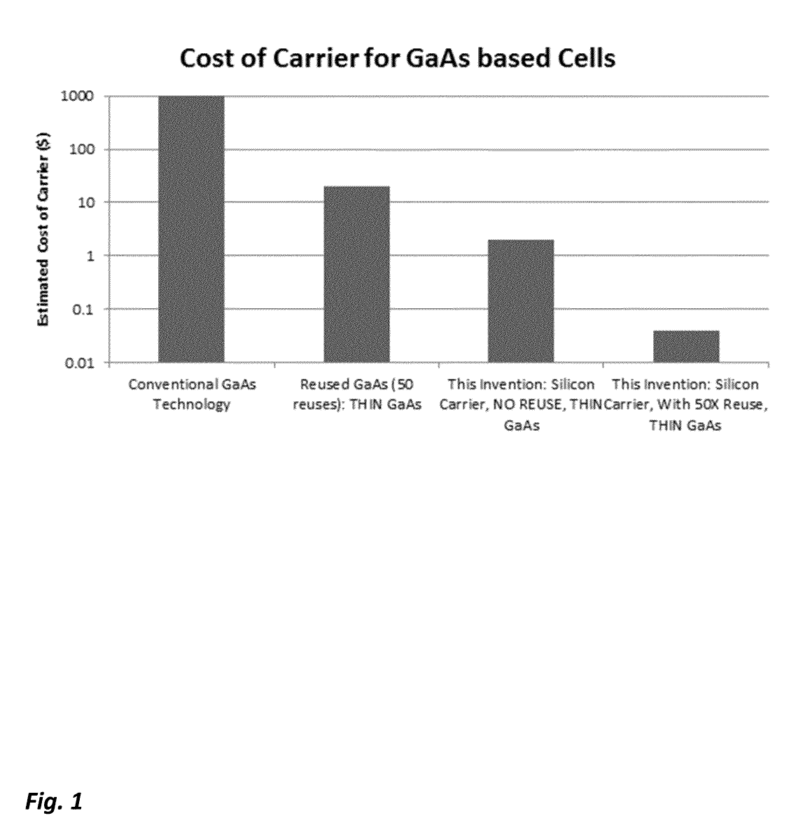

Further, the silicon carrier wafer thickness, and corresponding cost, may be reduced depending on desired reuse—in other words wafer reuse may require a thicker carrier wafer (depending on the number of desired reuses thickness in the range of 500 um to 1.5 mm), whereas the wafer may be thinner (100 to 250 um) for a single use (or a modest number of reuses, for instance, up to 10-20), thus, a wafer used for a single process will comprise less material and cost less. FIG. 1 is a graph showing the cost reductions enabled by using a crystalline silicon carrier as compared to a GaAs carrier (plotted on the log axis). The figure assumes GaAs as the thin absorber only to demonstrate the effectiveness, although the disclosed subject matter is not limited to GaAs but rather is applicable to a number of mono-crystalline direct band gap materials including but not limited to the ternary alloys of GaAs and/or other III-V compound semiconductor materials such as GaN. As can be seen in FIG. 1, significant cost reductions may be achieved by using a crystalline silicon template carrier and manufacturing costs may be further reduced through the reuse of crystalline Si carrier (even through a modest number of reuse cycles from a few to 10's, without a need for very large reuse cycles). FIG. 1 shows the cost of the carrier (shown as a representative example for comparative purposes). In the conventional technology embodiment the active absorber is the top few microns and thus is included in the cost of the much thicker starting GaAs (or Ge) substrate. In the other three embodiments shown in FIG. 1 additional costs may be associated with growing the solar solar cell absorber and the separation/release technology from the crystalline silicon template carrier. However, these additional costs are lower than the materials savings achieved by not using expensive GaAs wafers as templates/carriers. In addition, epitaxially grown thin (form submicron up to about 10 microns thickness) GaAs and/or related III-V binary or ternary compound semiconductor layers may provide additional efficiency advantages over the cells made on GaAs wafers based on the prior art conventional technology (in which the wafer remains a part of the final solar cell) which further offset the cost of resulting solar cell (in $/W)—thus total cell formation costs follow similar trend as shown in FIG. 1.

Thin crystalline semiconductor solar cells made from thin film semiconductor substrates (TFSS) are reliably supported during solar cell manufacturing (for example using cost effective carriers) throughout solar cell fabrication process steps to enable handling and processing, and hence, substantially reduce and/or prevent the risk of mechanical yield loss. Since both sides of the solar cell (frontside and backside) are processed, two carriers are used providing a robust thin cell manufacturing process. Choice of carriers and carrier material may include the following considerations. The carriers should be cost-effective to keep manufacturing costs low. Second, at least one of the carriers should be able to withstand relatively high temperature processing required in cell manufacturing, for instance, the MOCVD processing temperature for epitaxial deposition of the compound semiconductor layer(s), such high temperature covering the range of approximately 300° C. up to about 800-1000° C. However, specific processing temperatures may vary particularly at the high end of the range, which may be determined by the specific cell materials and the MOCVD processing temperature for such materials. In addition, if only one of the carriers is able to support high temperature cell processing (for example high-temperature processing, such as the MOCVD processing, to form the cell substrate as well as cell backside structure processing) the process flow may be designed such that all high temperature processing steps are performed on the high-temperature-capable carrier (crystalline silicon template in this invention). Third, at least one but not necessarily both of the two carriers should preferably be able to withstand wet chemical processing commonly required for manufacturing solar cells. For example, wet processing steps may include, but are not limited to, cleaning and removing of any residual porous silicon after detachment from the template carrier, as well as selective etching of the intermediate buffer layer. Fourth, after partial or full cell processing on the first side (in other words the cell side opposite the crystalline silicon carrier template), the thin cell (TFSS), along with constituent components and intermediate layers if applicable, may be efficiently detached from the carrier template (or first carrier) with high yield and transferred to a second carrier attached on the processed cell side allowing for processing of the second side of the cell (in other words the cell side/interface detached from the first carrier). Subsequently, in the cases where the first side was partially processed and further on the partially processed first side processing is needed, the remaining process steps (for example completion of final cell metallization) may be completed using a process as detailed below.

Cost effective manufacturing methods for large area (for example 125 mm by 125 mm or larger) thin absorber monocrystalline III-V compound semiconductor based solar cells in highly cost effective manner are provided. Although specific examples are detailed with reference to a thin film GaAs solar cell absorber, aspects of the disclosed subject matter are applicable to a wider class of materials which may form highly efficient solar cells and are conducive to being grown on porous silicon through appropriate intermediate layers which accommodate the lattice mismatch between the grown compound semiconductor layer(s), such as binary and/or ternary III-V semiconductor layer(s) including but not limited to GaAs and/or AlGaAs and/or GaN, and the crystalline silicon template.

Further, the large reduction in the cost of high efficiency GaAs solar cells as disclosed herein may also be applicable to these alternative materials. Cost reduction measures of the disclosed subject matter include, for example:
A thin GaAs layer (about 0.5 micron to 10 microns) may be formed by a suitable vapor-phase deposition method, such as a high-productivity MOCVD or MBE reactor, thus keeping material cost of the layer minimal.
GaAs is grown on a starting crystalline silicon wafer serving as a template (single-use or multiple uses through reuse) using appropriate intermediate buffer layers to accommodate lattice constant difference or mismatch between crystalline silicon and the grown compound semiconductor material (such as GaAs). Crystalline Si is a substantially lower cost material than GaAs. Thus, even when the Si template is desired for a single use and not be reused, forming a thin GaAs layer on a crystalline Si handler/carrier or template wafer provides significant cost reductions as compared to either a GaAs wafer or a reused GaAs wafer as the cost of an Si wafer is significantly (at least by about 10× to 100×) lower than that of a GaAs wafer. The practical number of reuses of a GaAs wafer limits the GaAs wafer process to substantially higher cost than the cost of single use Si wafer). Additionally, forming a GaAs solar cell absorber on a crystalline Si starting wafer serving as a template/carrier allows for more versatility in cell processes (due to mechanical strength and high temperature stability and yield strength of silicon as compared to gallium arsenide) in addition to being a cost effective carrier for cell processing.
Further, the crystalline Si template may be subsequently reused for growing more GaAs based solar cells. Thus, the already low cost of the Si carrier silicon wafer may be further reduced by amortizing its cost over several solar cells.
Tool cost (Cap Ex) as well as depreciation cost may be further reduced if GaAs growth is performed in a very high-productivity CVD epitaxial reactor using existing high volume platform which is configured for MOCVD, as opposed to conventional much lower throughput MOCVD methods. However, the disclosed subject matter does not preclude standard MOCVD or MBE or any other suitable GaAs (or compound semiconductor) growth techniques.

Large-area crystalline silicon cells often have areas at least as large as 150 cm² and may be as large as 243 cm² or 441 cm² or above. If GaAs is grown (for example by high-productivity MBE or MOCVD), the cost of the GaAs absorber itself can be made minimal as only sufficient material thickness needed for efficient absorption is grown (for example a GaAs layer with a thickness of up to about 2 to 5 microns). Comparatively, known methods require starting GaAs wafers which are about 150 microns up to 100's of microns thick to provide reasonable mechanical strength (although still much weaker and more brittle than crystalline silicon wafers) and to ensure their mechanical integrity, even though the main solar cell absorber only needs few microns of the compound semiconductor material. In other words, the thick GaAs wafer is used to provide both light absorption (either directly in the top surface of the bulk wafer or in the epitaxially grown solar cell absorber stack) and layer structural support. In addition, the method of handling thin GaAs through the cell process after it is detached from the silicon template can also be made both highly robust (high yielding) and cost effective, leading to a a dramatic reduction in the cost of a high efficiency, large area GaAs solar cell.

For a proper cost comparison between conventional technology and the disclosed subject matter, substrate cost should include the cost of thin vapor-phase-deposited GaAs (material, consumables, capex, depreciation of the reactor), the cost of the crystalline silicon wafer on which it is grown, and the cost of making the porous silicon (detachable layer) and any other sacrificial intermediate buffer layers. The cost of the crystalline Si wafer, even without reuse, is very low as compared to a GaAs wafer (again, even if the GaAs wafer is reused for 50 times, which may be a practical reuse limit of GaAs with sufficiently high yield, given its fragility). The Si wafer may be amortized and its cost is further reduced by reusing the wafer for subsequent substrate formations. Reuse of silicon wafer template is much more practical and much higher yield than that of GaAs (or even Ge); however, even without reuse a Si based template provides significant cost savings.

In addition, since crystalline Si wafers are available in relatively large sizes and in large manufacturing volumes (for example as large as 300 mm in diameter and comparably large square shaped wafers), GaAs based solar cells may be fabricated at the same size scale as crystalline the Si wafer and at lower cost per watt as compared to a crystalline Si based solar cell due to the high cell efficiency for GaAs compared to silicon absorber. In contrast, because GaAs layers are often grown on either Germanium or GaAs wafers which are economically available in smaller sizes such as 100 to 150 mm in diameter (and at much higher costs compared to silicon), the GaAs solar cell size is also limited to 100 to 150 mm in diameter (or 125 mm×125 mm pseudo square). The material cost of larger area Germanium or GaAs wafers, the brittleness (increased with size) and lower yield strength of the materials compared to crystalline silicon wafers, and lack of economies of scale (again compared to crystalline silicon wafers), have thus far limited large area thin film GaAs based solar cell manufacture.

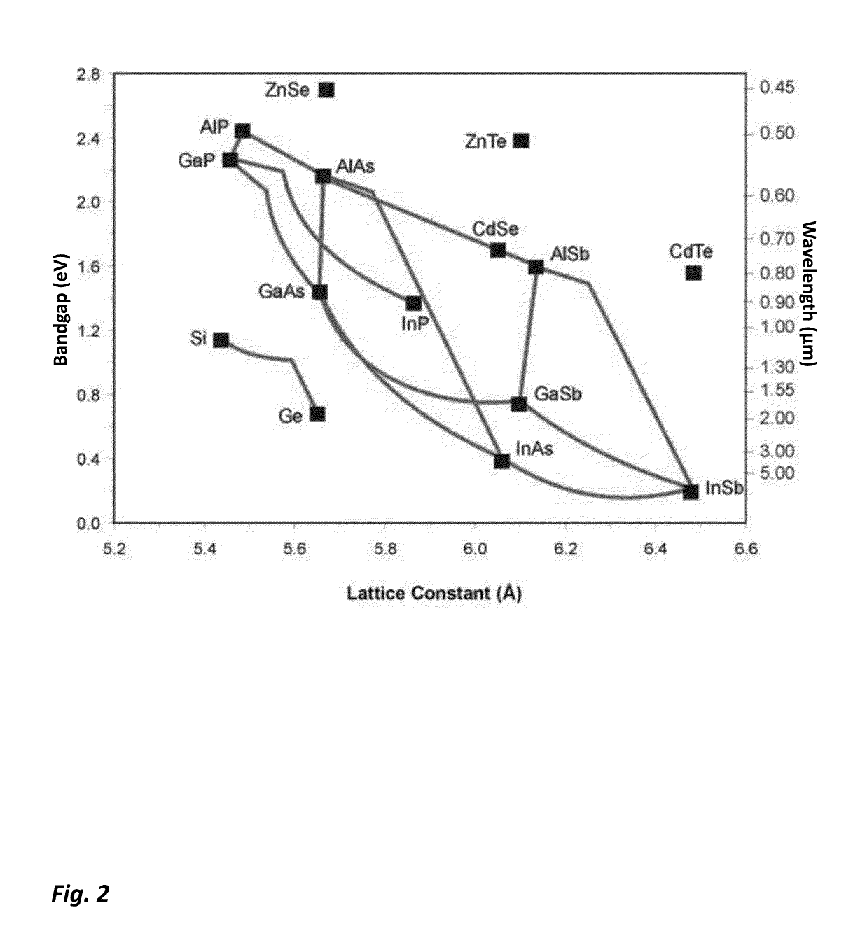

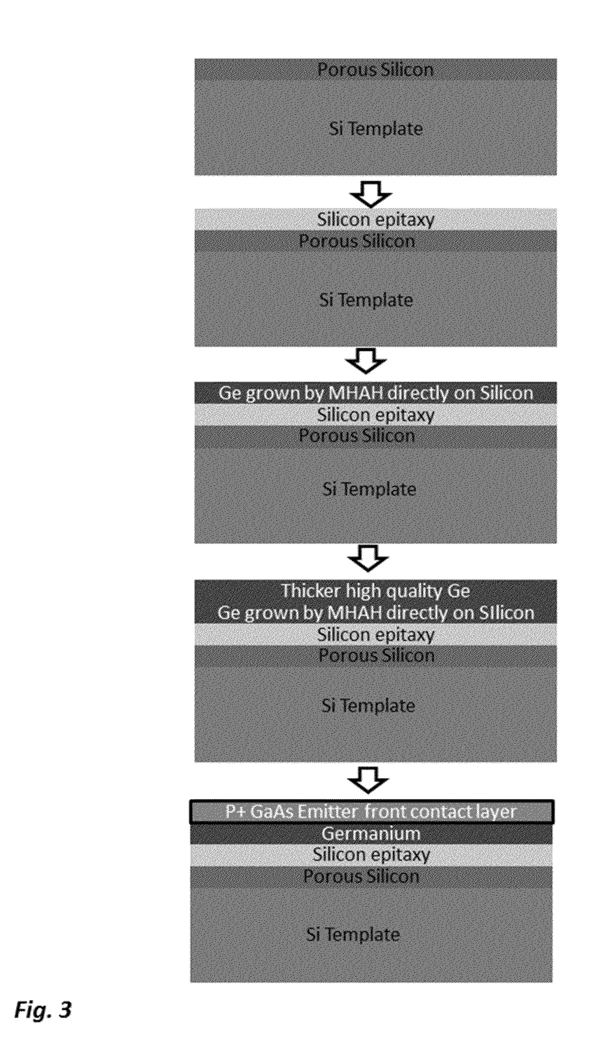

A key aspect of the disclosed subject matter is the growth of high quality GaAs (or like materials) on a crystalline Si wafer used as a carrier and epitaxial seeding template. A challenge for growing GaAs directly on Si is overcoming the lattice mismatch between crystalline GaAs and silicon. If GaAs is grown directly on Si, the GaAs layer will be highly defective with a very high density of dislocations and will be essentially useless for high efficiency solar cells. FIG. 2 is a graph showing energy bandgap vs lattice constant for various direct and indirect bandgap semiconductors, including those for GaAs and Si.

Two primary methods are provided to overcome the difficulties of forming a high quality (low dislocation density) GaAs layer on a crystalline Si substrate. Each of these methods may utilize different orientations and cuts of a starting silicon substrate as is conducive to yield superior GaAs film growth and lowest defect density.

Method 1.

High quality GaAs (or like materials) may be grown on a crystalline Si carrier template using an intermediated Ge layer. For example, we first form a sacrificial porous silicon layer (in some instances having at least two different porosities) on a starting crystalline silicon template along which the separation of the GaAs layer from the template occurs. Porous silicon may be formed using an anodic etch process in the presence of HF acid and IPA on the top surface of the crystalline Si template wafer (for example, preferably a p-type single crystal Si wafer) using a high productivity porous silicon manufacturing tool (in some instances having a throughput as high as 640 wafers/hour, have been demonstrated with porous silicon high-volume manufacturing equipment). Specifically, the porous silicon layer may be formed by one of two primary techniques as follows: (i) deposit a thin conformal crystalline silicon layer (in one embodiment, a p-type boron-doped silicon layer in the range of 0.2 to about 5 microns) on an n-type template substrate, using silicon epitaxy, followed by conversion of the p-type epitaxial layer to porous silicon using electrochemical HF etching; or (ii) directly convert a thin layer of the template substrate (in one embodiment, a p-type template) to porous silicon (in one embodiment, in the thickness range of 0.1 to 10 microns and more specifically in the range of 0.2 to approximately 5 microns).

Porous silicon layer porosity and thickness should be optimized to achieve two key functions. First, it should be porous enough (in other words have a sufficiently high porosity) such that it allows an on-demand separation of the substrates grown above/on it from the silicon mother template. Second, it should be sufficiently non-porous (in other words have a low enough porosity on the surface of the porous silicon layer) to ensure the transfer of monocrystalline information from the template to the substrate with high fidelity (effective epitaxial seeding). For example, a bi or multi layer porous silicon having at least two layers of different porosity may be used. The first porous layer (or the top layer) formed is a lower porosity layer (for example, this can be a layer with a porosity in the range of, but not limited to, 10% up to 40%). This is followed by the second porous layer (buried layer) with a higher porosity (for example, this can be a layer with a porosity in the range of, but not limited to, 45% up to 75% porosity) which is formed underneath so that it is closer to the template and separates the lower porosity layer from the template. In other words, dual layer of porous silicon having a first high porosity layer covered by a top lower porosity layer. Other configurations such as monolayer (such as with a single porosity in the range of about 25% to 40%) or trilayer or graded-porosity porous silicon are also possible. The sacrificial porous silicon also serves as an epitaxial seed layer for subsequent growth of either an intermediate layer (such as Germanium) or a thin single crystal Silicon layer which then serves has an intermediate layer for subsequent layers.

Subsequently and upon formation of the sacrificial porous silicon layer, which serves both as a high-quality epitaxial seed layer as well as a subsequent separation/lift-off layer, a thin intermediate layer (for example a layer thickness in the range of less 10's of nm up to several microns) of monocrystalline silicon is optionally formed on the porous silicon layer using Epitaxy or epitaxial growth, after performing a hydrogen pre-bake to remove the native oxide and to improve the epitaxial seeding properties of the porous silicon surface. The monocrystalline silicon layer may be formed, for example, by atmospheric-pressure epitaxy using a chemical-vapor deposition or CVD process in ambient comprising a silicon gas such as trichlorosilane or TCS and hydrogen. The thickness of the epitaxial silicon should be minimized to reduce cost while having sufficient thickness to support optimal subsequent processing.

The epitaxy may be cost effective and use low cost atmospheric pressure process with Trichlorosilane (TCS) or alternatively low-pressure silane based (or dichlorosilane based) silicon epitaxy may be used. The silicon substrates with porous silicon may be pre-baked in a pure hydrogen ambient (for example at a substrate temperature in the range of about 1000° C. up to 1150° C.) upon being loaded into a batch epitaxial chemical-vapor deposition (CVD) reactor. This hydrogen pre-bake perform two important tasks: 1) it removes the residual native oxide from the surface of the porous silicon layer; and, 2) it creates a thin (on the order of a few nm up to about 10 nm) relatively continuous layer of monocrystalline silicon seed layer by closing the surface pores and making the surface an excellent seed surface for subsequent epitaxial silicon (and/or intermediate buffer layer) deposition. The thickness of the epitaxial silicon should be minimized to reduce cost while having sufficient thickness to support optimal subsequent processes. High quality, single crystal epitaxial growth on top of porous silicon with defect density less than 3,000/cm² and with minority carrier lifetimes exceeding 500 μs may be formed. It is possible to eliminate this epitaxial silicon deposition step completely and proceed to the epitaxial growth of the germanium-containing intermediate buffer layer immediately following the hydrogen pre-bake process in the epitaxial deposition reactor.

A thin crystalline Germanium layer is then formed/grown on the thin epitaxially grown silicon layer (or alternatively directly on the hydrogen-prebake-treated porous silicon layer). A substantially defect free Ge layer (with defect density <3e6 cm²) may be grown on the Si as the Ge layer is lattice mismatched by 4% as compared to Si; however if grown as is, the Ge layer may have a larger number of defects. Thus, the defect density in the germanium layer directly grown on silicon may be minimized using the following methods, for example. First, a thin defective layer of Ge is grown on the single crystal Si using an epitaxial reactor (preferably the same epitaxial reactor used for the initial hydrogen pre-bake and the subsequent optional epitaxial silicon growth). The reactor may be a CVD reactor such as that described above to grow a thin epitaxial silicon on porous silicon. The Ge growth is followed by multiple hydrogen anneals (MHAH) to reflow Germanium, in-situ, in the epitaxial reactor. Subsequently, a thicker Ge layer is grown on top of the annealed Ge layer. This technique for growing Germanium directly on Silicon may yield a defect density as low as 2×10⁶ cm⁻². Additionally, other techniques relying on multiple anneals as well as grading techniques, where layers are gradually changed from pure silicon to pure Germanium by going through intermediate SiGe layers, may also be used to grow sufficiently high quality Germanium on top of Silicon grown on porous silicon. High-quality GaAs, which is relatively closely lattice matched to Ge, may then be directly grown on the aforementioned Ge layer, with relatively low dislocation density. For example, GaAs growth may be performed by MOCVD, MBE, or also directly in the same high volume epitaxial growth reactor used for the initial hydrogen pre-bake, optional epitaxial silicon, and subsequent epitaxial germanium layer deposition and anneals (such as a high-productivity batch CVD epitaxy platform). The epitaxial Silicon and Germanium layer thicknesses should be minimized to keep costs down while ensuring high quality GaAs may be grown on top of these layer stacks. The high quality GaAs layer formation may be followed by partial cell processing which may entail growing window and back surface field layers (example in lattice matched AlGaAs layers), and metallization. The (in some instances partially processed) GaAs layer, along with intermediate layers if present, is then separated and lifted off from the template along the mechanically weak sacrificial porous silicon layer (preferably through a mechanical detachment and release process).

FIG. 3 shows the cross sectional diagrams indicating the growth sequence described above. Specifically, processes are presented for growing large area GaAs layers on top of Silicon substrates using porous silicon seed/separation layer and Germanium intermediate buffer layer. While the p+ GaAs emitter front contact layer is shown as a cell structure example, this layer may be differently doped and may provide different functions depending on the specific cell architecture. High-efficiency GaAs based single junction or multi-junction solar cells may subsequently formed on top of this GaAs layer. The area of the GaAs solar cell may be as large as the area of the starting Silicon wafer which may result in 156 mm×156 mm (and as large as 210 mm×210 mm or even larger) sized GaAs based thin solar cells.

Method 2.

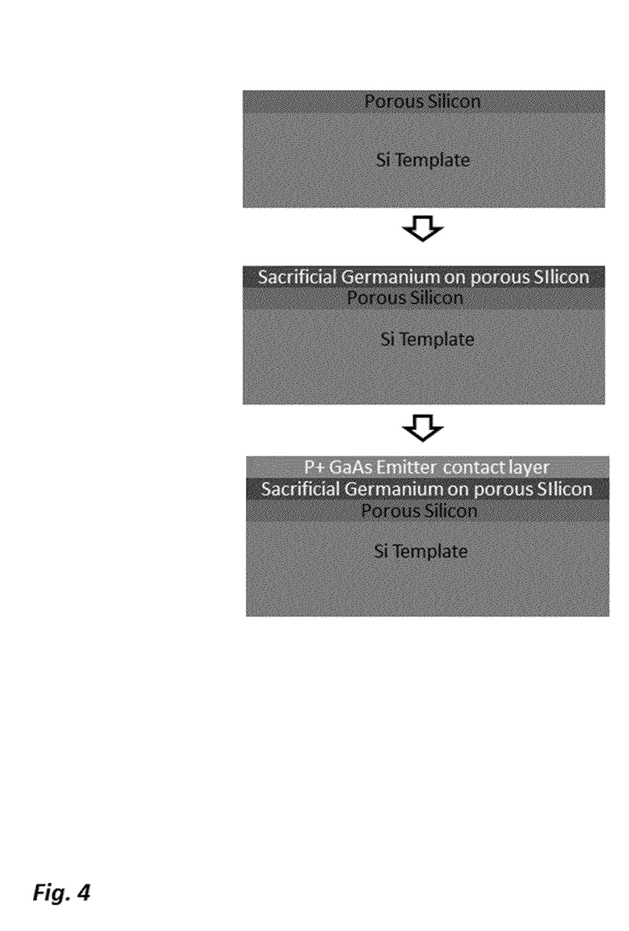

The aforementioned process may be modified to provide alternative processes for growing GaAs on Silicon template with intermediate layers. In one embodiment, Germanium is grown directly on top of the porous silicon layer without a need for the initial seed layer of epitaxial silicon. Several methods are available. In one of the methods a Germanium layer is grown using surfactant mediated epitaxy directly on porous silicon. (for more detail see T. F. Wietler et. al., “Relaxed Germanium on porous silicon Substrates, ISTDM 2012 which is hereby incorporated by reference in its entirety). In another method, prior to the growth of the thin Germanium layer the silicon substrate containing the porous silicon layer is first pre-baked in hydrogen (for example at a substrate temperature in the range of about 1000° C. up to 1150° C.). This hydrogen pre-bake performs two important tasks: (1) it removes the residual native oxide from the surface of the porous silicon layer and, (2) it creates a thin (on the order of 10 nm) continuous layer of monocrystalline silicon seed layer by closing the surface pores, making the surface an excellent seed surface for subsequent epitaxial Ge deposition. Single crystal Germanium is then directly formed on top of the annealed porous silicon layer. In general, the Ge layer growth may be a multi-step process similar to the MHAH process described above with intermediate, multiple anneals to improve the defect density. The high quality Germanium layer formation may then be followed by vapor-phase growth of GaAs. FIG. 4 are cross sectional diagrams shows the growth sequence described above.

FIG. 4 depicts the process for growing large area GaAs layers on top of a Silicon template using porous silicon and sacrificial Germanium. Note, Germanium is directly grown on top of porous silicon (after a hydrogen pre-bake of the silicon wafers containing porous silicon, in the temperature range of approximately 1000° C. up to 1150° C.) as compared to an intermediate Silicon layer as was shown in FIG. 3. Once again P+ GaAs is shown only as an example and generally, the top GaAs layer may be any doping or other lattice matched material according to the requirements of the cell architecture.

In yet another GaAs on Si template embodiment, the starting substrate may be a <111> oriented Si wafer. A top Si wafer layer is converted to porous silicon and GaAs is directly grown on it. GaAs is more amenable to be grown on top of a <111> oriented Si wafer. This method may also be combined with the aforementioned techniques including an initial hydrogen pre-bake of silicon wafers with porous silicon followed by an intermediate Germanium layer growth to further reduce the GaAs defect density. Further, any of the aforementioned GaAs formation methods are extendable to currently commercially available 300 mm diameter starting silicon wafers which correspondingly increases the size of the solar cells to 300 mm in diameter. An increase in cell size increases the power generated per cell which result in further solar cell manufacturing cost reductions.

Si Wafer Template Reuse.

Although not required for the majority of cost reduction and described herein as one embodiment, reusing the Si template may amortize and further reduce the templates cost per cell. When desired, the reuse of the silicon wafer hinges on the ability to separate it successfully from the stack on top of porous silicon (for example an epitaxial Si/Ge/GaAs/cell layers stack in the case of method 1 or an Ge/GaAs/cell layers stack in the case of method 2 or simply GaAs/cell layers if grown on a <111> Si wafer). Consumption of the template during reuse should be limited as porous silicon formation and template reuse reconditioning and cleaning processes use Si material and thus reduce template thickness. Lift-off release yield may be increased depending on the porous silicon seed and release layer. In a bi-layer porous silicon layer, the porosity of the higher porosity buried porous silicon layer underneath the lower porosity porous silicon layer may be tailored such that the release is performed by chucking the assembly and mechanically pulling away and lifting off the grown layer stack from the reusable silicon template. Residual porous silicon may then be cleaned off the surface of the template, and an optional surface polishing and/or reconditioning performed if necessary.

Several factors may contribute and/or dominate the overall cost of GaAs solar cells. First is the cost of the GaAs material itself. This is may be reduced by ensuring that the amount of GaAs used is minimal by reducing the thickness of the GaAs layer while ensuring it is thick enough for sufficient or full light absorption (for example approximately less 3 um thick). This is the minimal layer thickness as GaAs is not used for mechanical strength and reinforcement. The thin layer may be directly deposited using a suitable high-productivity batch vapor-phase deposition method, such as MOCVD or MBE. In operation, the GaAs layer thickness may be reduced to submicrons depending on efficiency requirements, cell design architecture, and GaAs layer material quality. Second, cost is related to the cap ex. depreciation and consumables, and throughput of the reactor which may dictates how many reactors are needed for a given solar cell manufacturing line. A typical GaAs deposition may use MOCVD or MBE (in some instances higher throughput MOCVD may be desired over MBE). Alternatively, a standard high-volume batch CVD epitaxy may be used grow GaAs on Germanium in which case the reactor should be operated in CVD mode (for example using germane or digermane and hydrogen) for germanium epitaxy and in MOCVD mode (for example using metal-organic precursors for As and Ga along with the necessary dopant sources) for undopd and doped GaAs and AlGaAs deposition. Current solar-grade, high throughput, low depreciation epitaxial reactors (in some instances designed and conducive for silicon and Germanium growth) may be modified to grow GaAs by adding the suitable liquid delivery (for example Direct Liquid Injection or DLI) components, controlled heating of the metal-organic precursor delivery lines, and high-vapor pressure metal-organic sources.

The thin GaAs absorber and cell, once released from the silicon template, is supported for the remaining high yield solar cell processing steps. Once GaAs is deposited, and depending on cell architecture, partial solar cell formation steps may be completed while the thin GaAs layer is attached to and supported by the Si template (held by the porous silicon layer). The cost effective large area thin GaAs and accompanying layers (for example a layer stack between the GaAs layer and the porous silicon depending on the formation method used, accompanying solar cell components/layers formed on the GaAs substrate side opposite the template, in other words formed on the exposed GaAs surface) are separated from the cost effective mother template. The thin GaAs solar cell substrate should be supported throughout the remaining cell fabrication processes by a carrier or backplane. The carrier or backplane should be cost effective, withstand processing temperatures and wet chemical processes which may be required in subsequent cell processing, and provide a high yield seamless transfer from the first carrier (temporary reusable silicon template carrier) to the next (for example a low-cost permanent carrier such as a plastic laminate). The second carrier may be a permanent structure providing solar cell field support in various weather and wind conditions.

The second (for example permanent) carrier may be a low cost thin dielectric or polymeric sheet. Alternatively, the carrier may be a backplane such as a metallic layer or sheet which also serves as the contact and the mirror for the solar cell. Requirements for this supporting layer depend on the exact nature of the solar cell processes that follow, specifically relating to wet and high temperature processes. However, generally a carrier layer should supporting wet chemical processes and should be resistant to chemicals used in such processes, as well as have the capability to support temperatures required for high efficiency cell processes, may seal and protect any underlying metallization, and if applicable should have a coefficient of thermal expansion (CTE) matched for high temperature processing if needed. For the III-V cell processes, detailed subsequently, the high temperature processing requirements and the ensuing demands on the carrier material may be significantly mitigated.

In one embodiment, the second carrier (also called a backplane herein) may be prepreg. Prepreg sheets are used as building blocks of printed circuit boards and may be made from combinations of resins and CTE-reducing fibers or particles. The backplane material may be an inexpensive, low-CTE (typically with CTE<10 ppm/° C., or preferably with CTE<5 ppm/° C.), thin (usually 50 to 250 microns, preferably in the range of about 50 to 150 microns) prepreg sheet which is relatively chemically resistant to etching/texturization chemicals and is thermally stable at temperatures up to at least 180° C. (or preferably to as high as at least 280° C.). The prepreg sheet may be attached to the III-V solar cell backside while still on the template (before the cell lift off process) using a vacuum laminator. Upon applying heat and pressure, the thin prepreg sheet is permanently laminated or attached to the backside of the processed solar cell. Then, the lift-off release boundary (if needed) may be defined around the periphery of the solar cell (near the template edges), for example by using a pulsed laser scribing tool, and the backplane-laminated solar cell is then separated from the reusable template using a mechanical release or lift-off process. The subsequent process steps may include: (i) completion of the chemical porous silicon residue removal, texture, and passivation processes on the solar cell sunnyside, (ii) completion of the solar cell high conductivity metallization on the cell frontside or backside (which may also act as the solar cell backplane and provide structural support).

The viscosity of a prepreg resin affects its properties, and it is affected by temperature: At 20° C. a prepreg resin feels like a ‘dry’ but tacky solid. Upon heating, the resin viscosity drops dramatically, allowing it to flow around fibers, giving the prepreg the necessary flexibility to conform to mold shapes. As the prepreg is heated beyond the activation temperature, its catalysts react and the cross-linking reaction of the resin molecules accelerates. The progressive polymerization increases the viscosity of the resin until it has passed a point where it will not flow. The reaction then proceeds to full cure. Thus, prepeg material may be used to “flow” around and in gaps/voids in the desired attachment surface.

In another embodiment, a dielectric layer backplane carrier may be deposited using a myriad of direct write techniques such as screen print and thermal spray. And in yet third embodiment, the backplane material may be a patterned metallization layer which also serves as the contact and the minor material. Care should be taken to ensure that a metallic backplane is compatible with the subsequent process steps following the III-V substrate release from the silicon template. Importantly, the second carrier may comprise any combination of materials (for example a combination metallization/prepeg backplane) providing structural support to the thin large area III-V substrate.

Having provided methods for making larger area, inexpensive, GaAs based substrates, high efficiency III-V based solar cell structures that may be manufactured using this thin GaAs absorber are provided. Cell structures and architectures may be organized into the broad categories of single and multi-junction solar cells where multi-junction cells refer cells having two, three, or more junctions (as more junctions are added, the maximum possible efficiency increases dependent on other considerations). For example, a common 2-junction cell comprises GaAs on Ge. Further, both single and multi-junction cells may be formed in front and back contacted cell designs.

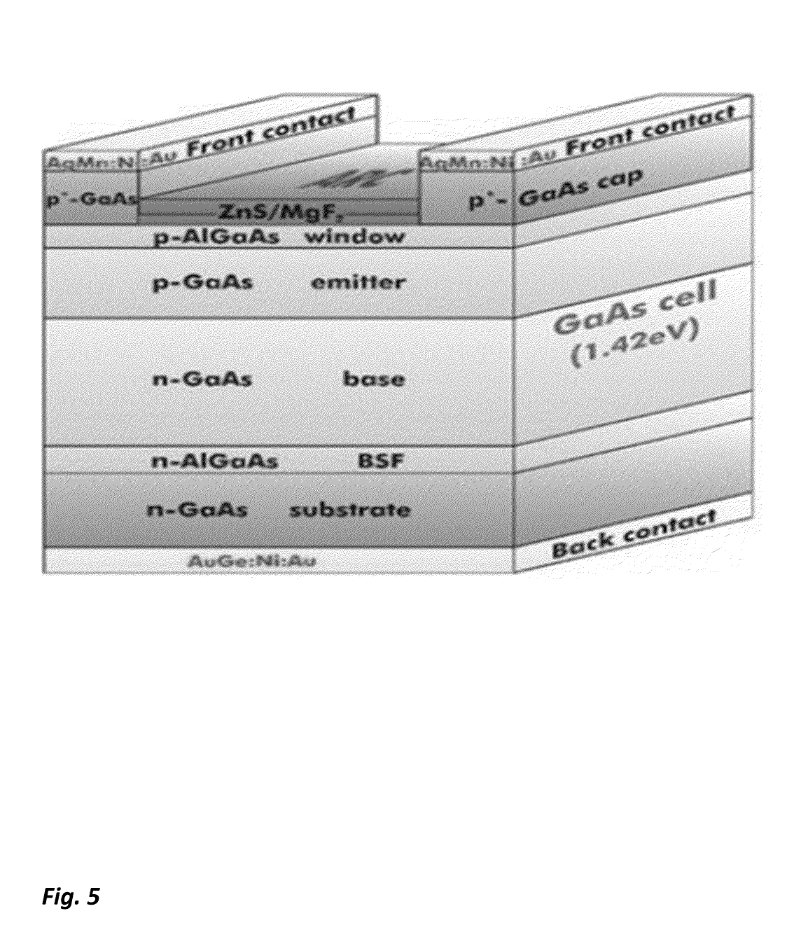

FIG. 5 is a cross-sectional diagram showing a standard single junction front-contact GaAs solar cell on a bulk GaAs substrate. As shown, the cell of FIG. 5 has an n-type GaAs base and the p-type GaAs emitter. In a general sense, it is also possible for the emitter to be n-type and base to be p-type. A p-type AlGaAs based widegap window layer is formed above the emitter to provide enhanced minority carrier passivation. Because the bandgap of AlGaAs is larger than that of GaAs, it lets relevant light in without absorbing the light. An antireflection coating is added to provide a larger coupling of light into the solar cell (for example, the Anti-Reflection Coating (ARC) layer may be made of a material such as ZnS). Also, in some instance the p-contact may require a heavily doped p-type layer. Below the n-type GaAs is the wider bandgap n-type AlGaAs which serves as a Back Surface Field (BSF) layer reflecting the minority carriers and reducing recombination. A typical base thickness may be in the range of approximately 0.5 μm to 2 μm to ensure that all photons up to ˜850 nm wavelength are absorbed. Because GaAs is a direct bandgap material, the absorption decreases dramatically beyond its bandgap dictated wavelength absorption. Further, cells made on bulk GaAs often do not have a way to reflect light back into the absorber. Thus the absorber may not get the benefit of a second reflection, resulting in it being formed on the thicker side (˜2 μm) to capture all the light. This inability to go thinner than 2 um thickness in conventional bulk GaAs technology results in a trade-off of increased recombination, as the typical bulk lifetime (˜20 ns) in GaAs is not sufficient to support recombination of free thick layers. This in turn may result in lower Jsc.

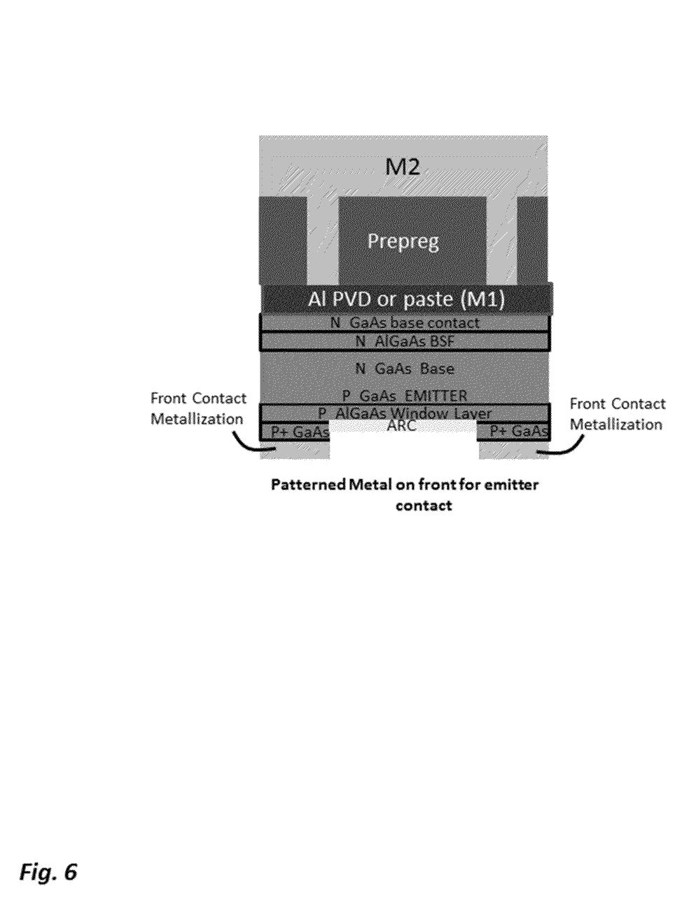

Front contact single and multi-junction thin solar cells formed on silicon carrier template are provided. In one embodiment, the structure comprises a standard stack of crystalline semiconductor thin films starting with the P+ GaAs contact layer, P doped AlGaAs window layer, P-doped GaAs emitter, n-doped GaAs emitter, n-doped AlGaAs BSF, and n-doped GaAs base contact layer (as shown in the cross-sectional cell diagram of FIG. 6). Thin GaAs based single junction front contact cell shown in FIG. 6 may have the advantage of light reflection from the backside metal which allows for the use of a thinner absorber layer. This in turn may provide increased light carrier collection and Jsc, and lower recombination volume and higher Voc.

A difference between the structure of FIG. 6 and traditional cell structures is that the back metal touching/contacting the n doped GaAs contact layer is followed by a dielectric backplane (which may also be a metallic or semiconducting backplane). The backplane has via holes through which another metal layer connects to the underlying metal in contact with the active N-type GaAs layer. In an alternative embodiment not shown, the metal connecting to the active n-doped GaAs is thicker and serves as the backplane itself, thus obviating the need for a subsequent dielectric backplane and additional metal layer. In this case, care has to be taken to ensure that the metallic backplane is compatible with subsequent processing.

A difference between the structure of FIG. 6 and traditional cell structures is that the n-type GaAs layer may be thinner (<1 um) because of the presence of the back minor, which allows a second pass for the light. Note, the exemplary metallization shown in FIG. 6 is Al and this should not be interpreted as limiting. Generally, the back metal may comprise of a number of conductive metals such as silver or copper as long as the contact resistance to n doped GaAs is conducive for high efficiency and the deposition techniques are cost effective.

In the cell structure shown in FIG. 6, compatible with thin grown GaAs based solar cells, the formation of a high quality back mirror from which the light is thrown/reflected back into the cell and the absorber gets a second pass, effectively doubling light path length, may provide for further decreases in the thickness of the thin-film absorber. Thus, the absorber may be thinner without compromising photon capture while increasing current collection due to less bulk recombination loss—potentially increasing cell efficiency as compared to a bulk GaAs device. Further, less recombination volume may provide a potentially higher open circuit voltage further increasing the efficiency. Thus, a thinner layer GaAs enabled by the virtue of having a thin film Solar cell, where there is a possibility of back mirror, results in two advantages: 1. Higher efficiency because of lesser volume of absorber, and lesser recombination, 2. Lower cost because thickness of the absorber can be less.

The thin film GaAs based solar cell architectures described herein may be based on GaAs growth on a silicon based template. The quality of back mirror reflection, relating to reflectivity and the specularity, may be tailored based on the choice of the metal and processing. Importantly, a similar structural skeleton may be used for fabricating multi-junction cells while utilizing the advantage of thin films. A multi-junction embodiment may use the cell basic structure outlined in FIG. 6, except with a modified growth process for forming multi-junction cells, and ensuring the necessary current matching between different junctions.

Back contacted III-V single and multi-junction solar cells, which may be either back junction or front junction, are provided. In a single junction back contacted/back junction embodiment, both the p and the n type metal is formed on the cell backside. As a result, the amount of light capture is increased as there is no parasitic loss of light from reflection from frontside metallization (for example a metal front grid). Thin films absorbers enable the formation of back contacted/back junction GaAs cells. This architecture is not preferred for thick Bulk wafers as traditionally, because of low lifetime and high absorption in GaAs most of the light is captured in the front of the cell. In addition, because of low lifetime the emitter is often positioned on the cell frontside where most of the light is absorbed. For the conventional thick GaAs wafer, moving the emitter to the back of a 200 μm thick cell will result in recombination of all photo generated carriers before they reach the back contacted backside of the cell. This limitation is overcome by using a thin film GaAs cell on Silicon template as proposed in this invention, thus enabling the back contact/back junction architecture. In a thin back contacted/back junction GaAs cell, the emitter may be positioned on the cell backside without compromising current collection because the thickness of the GaAs absorber is less than 2 μm.

An alternative embodiment of a back contact cell is a thin film back contact/front emitter cell where the emitter is positioned on the cell frontside but the contacts on the cell backside. Because the absorber thickness is small (a thin film in the range of), it may be possible to use laser or other techniques to go through ˜1.5 to 2 μm of GaAs, and form access vias to the front emitter from the backside for all backside contact metallization.

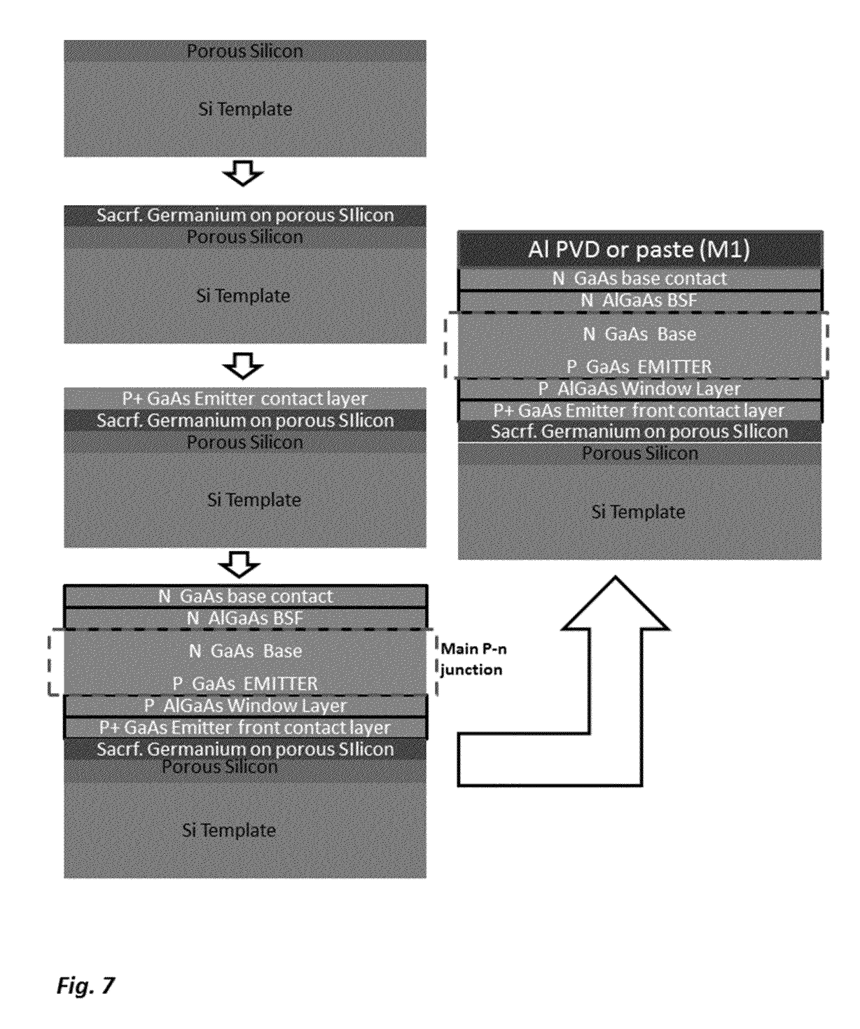

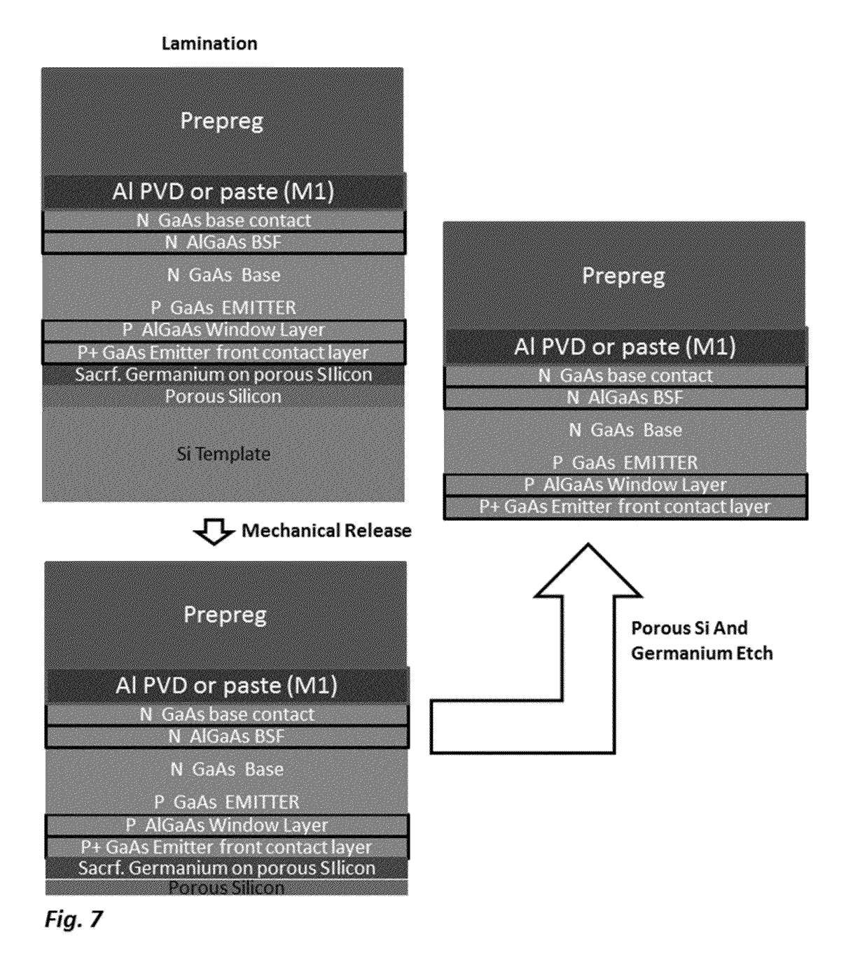

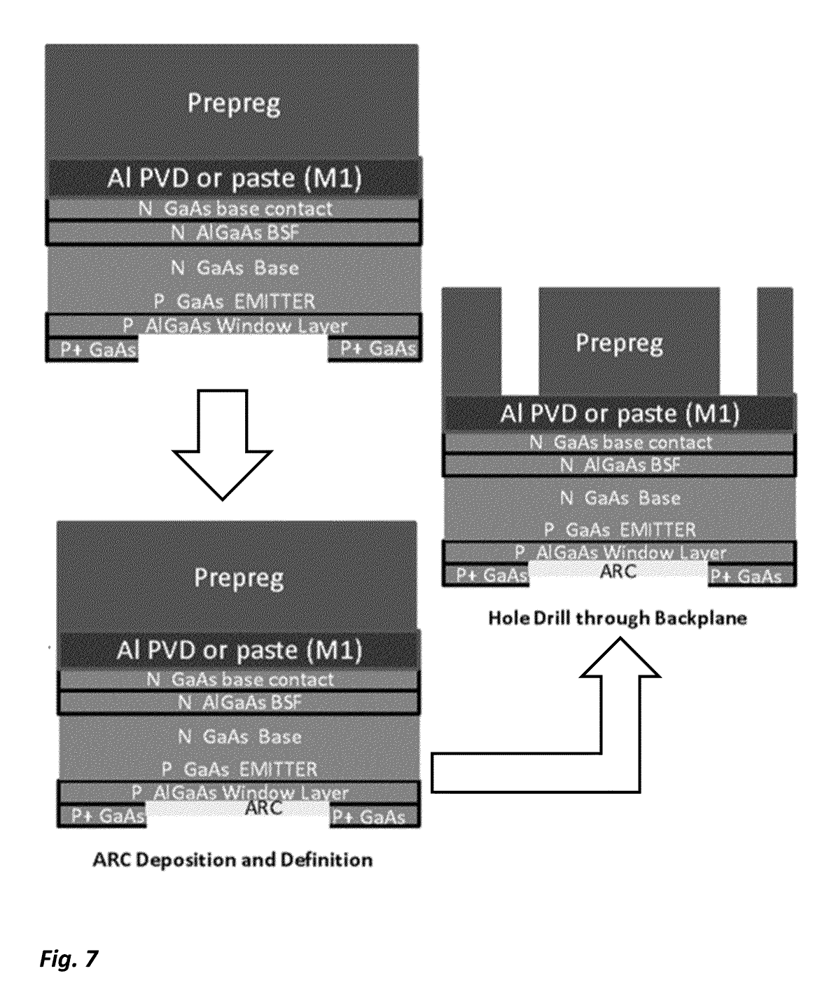

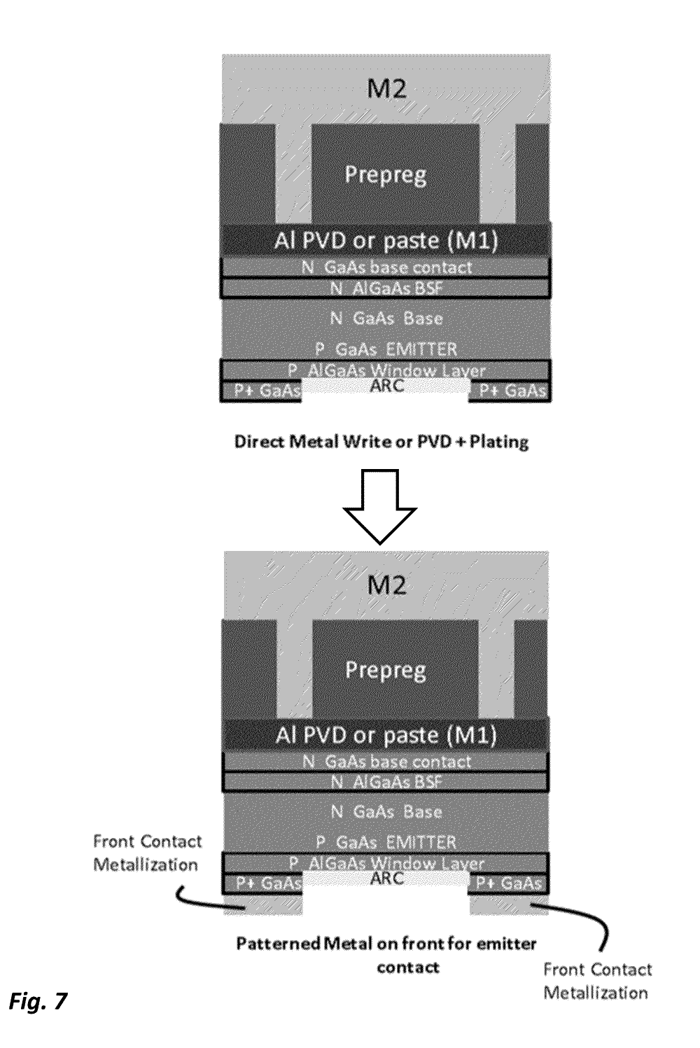

FIG. 7 are cross-sectional diagrams showing the formation of a single junction GaAs based cell by directly growing Ge on porous silicon The processing steps shown in FIG. 7 outlined in Table 1 below.

TABLE 1
A representative process flow for forming a thin film large area GaAs
cell on a Si Template.

| | |
|---|---|
| 1 | Anodic Etch of Si template for Porous Silicon Formation |
| 2 | In-Situ Hydrogen Pre-Bake (for example at approximately 750° C. to |
| | 1150° C.) and Germanium Epitaxy (for example at approximately |
| | 600° C. to 750° C.) |
| 3 | MOCVD or Epi growth of III-V layers (in some instances including |
| | doped, BSF, and window layers) |
| 4 | A1 Deposition (for example by A1 paste screen printing or PVD) |
| 5 | Lamination of prepreg or other cheap plastic or polymeric carrier |
| | material sheet or printed layer. The backplane may also be a metallic |
| | or semiconducting layer. |
| 6 | Lift-Off/Release (for example a mechanical release by chucking the |
| | assembly) |
| 7 | Cell frontside clean of porous silicon and sacrificial Germanium |
| | layers along separation interface |
| 8 | Contact layer definition on cell frontside |
| 9 | AR Deposition/Definition |
| 10 | Laser via hole drill in the backplane |
| 11 | Direct Metal Write process such as PVD, evaporation, screen |
| | printing, thermal spray, TWAS (Twin Wire Arc Spray), or cold spray |
| 12 | Frontside Metallization (for example using shadow mask PVD or |
| | direct write metal) |

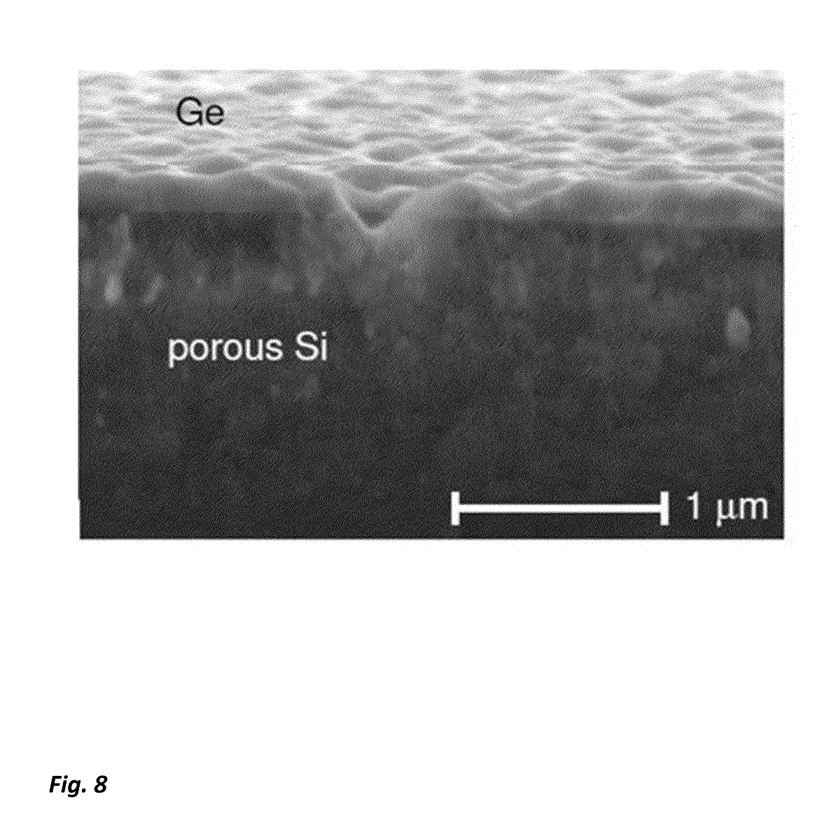

Germanium is grown directly on porous silicon using known methods. The process starts with silicon template. Generally, a porous silicon layer is created using anodic etch process (in HF/IPA). The thickness of this dual-porosity (or multiple porosity) layer is typically in 1 to 5 μm range, and it is a bilayer conducive to give both a high yield detachment from the template as well as a good quality epitaxy. Germanium is directly grown on top of the porous silicon after an in-situ hydrogen pre-bake. FIG. 8 is a scanning electron microscopic (SEM) picture showing a single crystal Germanium grown directly on porous silicon. Next, as both GaAs and any alloy of AlGaAs are lattice matched with Germanium, they may be grown on top of this layer with minimal defects, leading to a high quality material.

In one embodiment for manufacturing a single junction front contact emitter cell, the cell is designed such that the frontside (sunnyside) emitter is facing down toward the porous silicon. This method may be referred to herein as an emitter first approach. The method starts by growing a P+ GaAs layer used to contact the emitter metal (for example the emitter may formed of materials such as AgMn, Ni, Au). Next, a window layer of p-type AlGaAs may grown on top of p+ GaAs layer to provide very low surface recombination and velocity passivation for the emitter due to its larger bandgap. This may be followed by the formation of p-type GaAs emitter and n-type GaAs base layers which form the main solar cell diode. Subsequent to n-type GaAs formation, an n-type AlGaAs layer may grown to serve as the back surface field (BSF) for reflecting minority carriers away from the backside surfaces. Finally, an n-type GaAs layer serving as the base contact layer may be grown. The above described layers or stack may be grown in-situ in one epitaxial/MOCVD reactor or may use different reactors, and total thickness of the entire stack may be in the range of a few microns. For solar cell application, a high volume reactor capable of performing these growth steps with high throughput, for example a MOCVD reactor with a high growth rate, should be used. Alternatively, growth may be formed using a high volume epitaxial growth CVD reactor as described earlier.

Base contact metallization layer deposition may then be formed while the stack is on-template. Base contact metallization may be formed of materials such as, for example, Al, AuGe, Ni, or Gu. Al may have the advantage of being less expensive as compared to other conductive metals. Further, Al relatively easy to clean from the template and thus presents a relatively low risk metallization material. This metal layer (base contact metallization layer), referred to herein as metal 1 (M1), may be blanket deposited using known techniques such as screen printing, stencil printing, physical vapor deposition, or evaporation/sputtering. Key functionalities and requirements of this layer are to provide low contact resistance to the base as well as create a highly reflective back minor so that light will bounce back into the solar cell for another pass at absorption.

Subsequently, the second carrier or the backplane, (described before) may be bonded or laminated to the back of deposited Al—thus forming a backplane. The backplane may be attached by a number a methods. In one embodiment, the backplane is attached without holes and via holes for connecting the overlying metal are drilled after cell sunny side processing is completed. In another embodiment, the backplane has prepatterned via holes through which the second metal layer on top is connected to Metal 1. The prepatterned via holes may be temporarily sealed to protect from wet processing chemistry during cell front side processing, if such a process follows the attachment of the backplane. The via hole seal may be mechanically opened or opened by using a laser zap before Metal 2 deposition and after wet chemistry processing. Pre-patterned vias may be formed by directly printing the backplane with via patterns using screen or stencil printing. Alternatively, holes may be pre-drilled in a laminate material before lamination on top of metal 1. An advantage of pre-drilled or pre-patterned backplane it eliminates an on-cell drill step; however other factors may be considered when choosing a backplane.

The backplane layer provides several functions including: serving as a second carrier supporting the thin substrate during the cell front/sunny side processing (the side to be detached from the porous silicon/template). The backplane may also serve as a permanent carrier of the thin solar cell during field operation and thus should robustly support the cell in various weather conditions. The backplane may also protect the underlying M1 from the subsequent wet processing on the cell front side. In this case, this layer must be inert to the chemistry used in etching and cleaning the cell sunny side following cell detachment from the template along the sacrificial porous silicon layer.

Further, choice of backplane may be subject to additional considerations. In the case where the backplane is drilled after lamination, the backplane should be conducive to a rapid drill rate with a high selectivity stop on the underlying metal. The material may be inexpensive, light weight but structurally and mechanically supportive, and CTE matched to the underlying and attached layers if subsequent high temperature processing is desired. However, if only PVD layers and other subsequent lower temperature processing is performed, backplane CTE matching may be relaxed.

As an example, the backplane may be a printed circuit board prepreg material sheet with resin having a thickness in the range of approximately 25 μm to 200 μm. This standard laminant material is used in the PCB industry and material costs may be reducted to 15 cents per cell. Other plastics materials such as mylar or PEN TEONEX Q83, ULTEM plastic, or printed dielectric pastes may also be used as a backplane.

Using the backplane, the grown stack of Germanium, GaAs, and AlGaAs layers are released from the template. The preferred approach is to do this process using simple mechanical release. Here, the entire bonded assembly is chucked, while the top containing the substrate and grown assembly is pulled using a vacuumed chuck. Because buried porous silicon represents the weakest bonding force, the assembly separates from this interface. The process optimization of the porosity and thickness of the porous silicon aids this process. Subsequently, the template is cleaned of the residual porous silicon and is made ready for the fresh cycle of porous silicon etch into it. While, the substrate assembly on the backplane is cleaned up in an etching solution which etches the residual porous silicon as well as any residual layers including the intermediate and sacrificial Germanium layer. The etch is selective to the GaAs layer.

Subsequent cell front side processing may be performed on the thin substrate stack supported on the backplane after its release from the template. The front side processes may include deposition and definition of anti reflection coating (ARC), for example deposited using plasma sputtering. Backside cell processing may be completed by drilling holes through the backplane if applicable such as when the laminant was not pre-drilled or pre-patterned, for example using CO2 laser, particularly if the backplane comprises of prepreg resin. Alternatively, simple mechanical means or laser processing may also be used to form access holes. In some instances, laser drilling may drill several thousand holes in seconds. The holes/vias provide access to back side metal, M1. In the case where backplane was either pre-drilled or pre-patterened and sealed for wet processing, the temporary sealant may be removed mechanically, chemically, or using a laser depending on the type of sealant. Deposition of a final metal, referred to as metal 2 (M2) connects to M1 through the via holes in the backplane. M2 (for example a Al, Cu, or an AL based alloy) may be deposited by direct write using techniques such as evaporation, PVD, flame spray, twin ARC spray, or cold spray. Alternatively, M2 may be screen printed or plated. And if M1 is Al, M2 may a material such as Cu, Al, or AlZn; although, by using Cu and AlZn for M2 the cell may relatively easily be soldered inside a module and connected/interconnected to additional cells. In some process flows, the final step is the formation of front side metallization.

In one variation of the aforementioned flow, the ARC can be put down after the p+ GaAs layer is defined. This is followed by opening the ARC only in the areas where there is p+ GaAs layer and depositing front side metal. In another variation, the order of front side metallization can be changed and done before the backside drilling or right after it, but before M2 deposition. In yet another variation of the flow, a germanium layer can be used to contact to the cell.

In a variation of the process flow described in Table 1, steps 4 and 5 may be combined if a metallic backplane is used. In this embodiment, steps 10 and 11 entailing laser hole drill of the backplane and a direct metal write step may also be eliminated leading to a 9 step process.

Further, all of the above manufacturing methods and their variations may utilize a crystalline Si layer grown on porous silicon, followed by Ge layer growth and subsequent GaAs based cell growth instead of directly growing Ge on top of porous silicon. Choice between GaAs formation options may be dictated by the quality of the Ge layer possible by direct growth of Ge on porous silicon. Crystalline silicon formation on top of porous silicon is a well established process which may yield a high lifetime crystalline silicon layer for the subsequent growth of Ge on the single crystalline silicon. While several methods may be used to grow/form high quality Ge directly on crystalline Si with a defect density as low as 2e6 cm-2. These methods include, among others, a technique known as MHAH. For example, using MHAH after a thin Ge layer is grown directly grown on silicon the Ge layer is subjected to several anneals in presence of hydrogen, for example inside an epitaxial reactor. Subsequently grown Ge layers may then have quality and low defect density (a process detailed in FIG. 3). After formation/growth of a high quality Ge layer the subsequent cell processing may be performed as outlined in FIG. 7 including all the variations described herein. It is to be noted, etching after the cell release should remove the sacrificial Silicon and Ge layers, if present.

In an alternative embodiment of a front contact cell process, specifically a front contact single junction solar cell, the emitter is grown toward the end and the base is grown first near the porous silicon. In other words, the emitter is formed towards the end of the process, referred to herein as an emitter-last approach. Both Ge growth directly on porous silicon or Ge growth on an intermediate crystalline silicon layer may be used with the emitter-last manufacturing approach. For example, on top of the grown Ge layer, following layers may be grown in order: n-type GaAs, followed by n-AlGaAs BSF, followed by n-GaAs base, p-type GaAs emitter, p-AlGaAs window layer and p+ GaAs emitter contact layer. Thus the emitter is positioned at the top of the growth stack (for the cell frontside/sunnyside) and the base is toward the template and porous silicon (for the cell backside). Patterning of the p+ layer followed by ARC may be performed while the assembly is still on template. This is followed by metallization, such as a metal grid, on the cell topside (frontside) connecting to the top emitter. A transparent backplane layer (for example transparent plastic or mylar) may then be laminated on top of the metallization. Backplane transparency may be in wavelength relevant for GaAs absorption, for example in the range of 350 nm to 900 nm. Except for transparency, additional requirements for this backplane material may be relaxed as, post-release, the backplane only has to a withstand metallization step on the backside and a porous silicon and germanium clean—in other words there are no high temperature cell processing steps. The solar cell assembly may then be released using mechanical release as described above. This may be followed by drilling holes into the backplane material for front metal contact (in other words holes are positioned to contact to the front metallization pattern). Frontside metal may be directly written overlapping and limited to the underlying front metal coverage. The amount of metal coverage on the front may be dictated by the trade-off between light blocking and series resistance of the emitter. Then, residual porous silicon, sacrificial silicon (when applicable and an intermediate single crystalline Si layer is formed), and sacrificial germanium are etched away, stopping at the n-GaAs layer. A blanket metal, such as Al, an Al alloy with Zinc, solder and Cu with Al, or Au based contacts, may then be deposited in contact with GaAs on the cell backside.

In a variation of the above process, the transparent backplane may be deposited on top of the P+ GaAs contact layer. Subsequently, via holes are opened and metal grid contacts the P− GaAs contact layer through the via holes. The transparent laminate may be predrilled or drilled after lamination as described above.

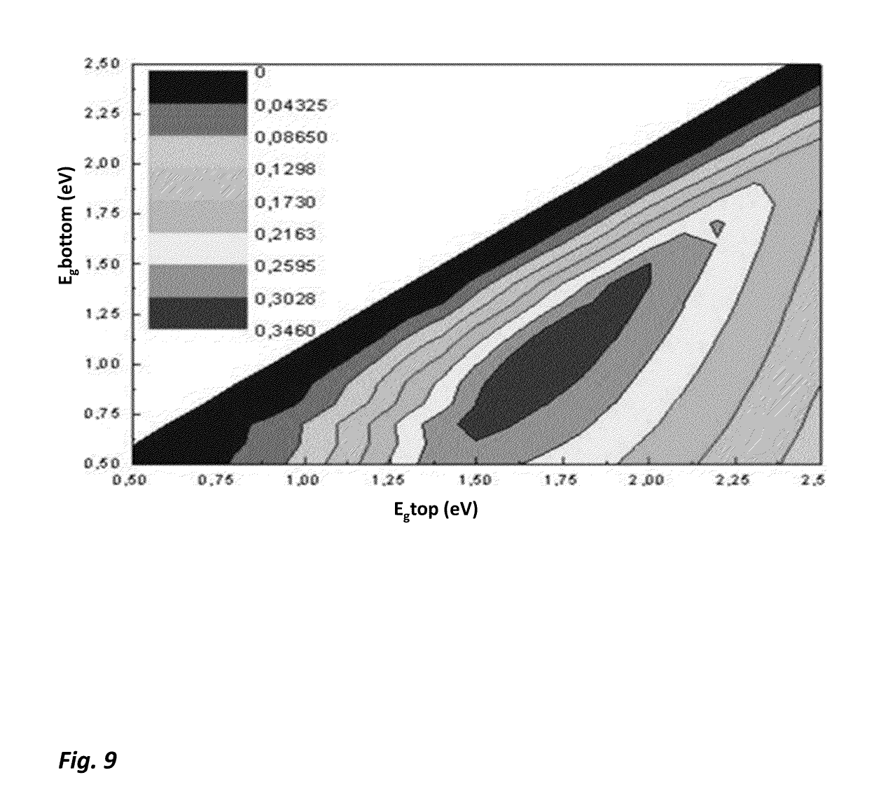

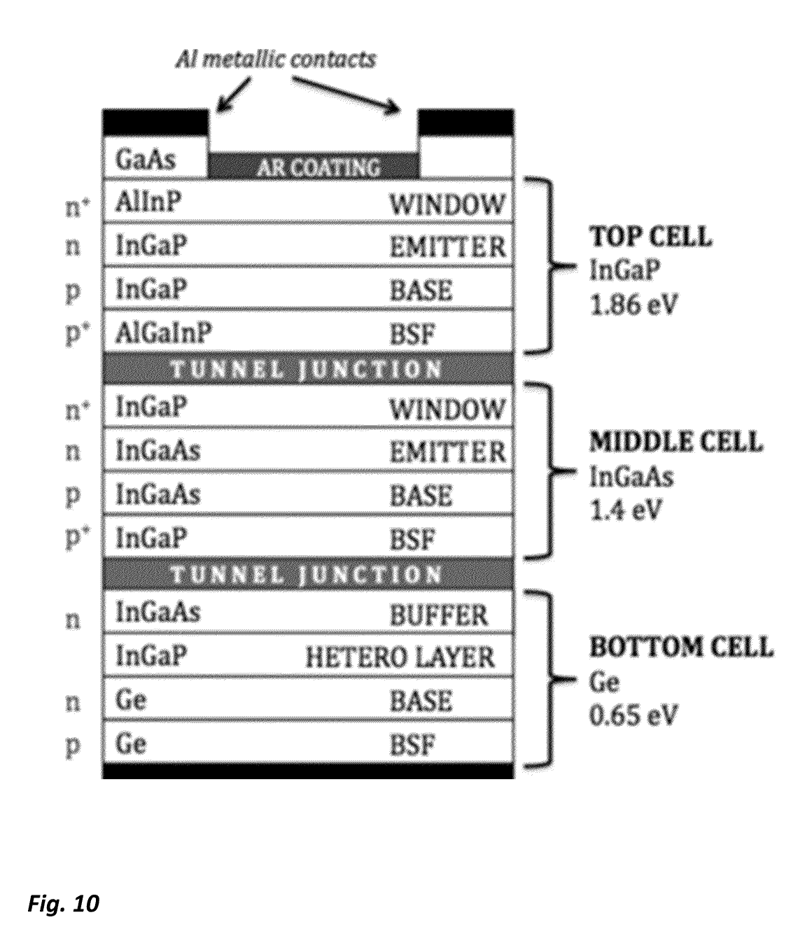

In addition, front contact multi-junction cells may be formed using the manufacturing methods described herein by introducing the necessary additional thin film growth, for example formed using MOCVD processes. FIG. 9 is a graph showing the maximum achievable efficiency as a function of the choice of the bandgap of top and bottom materials in a two-junction tandem cell. FIG. 10 is a cross-sectional graph showing a typical multi-junction cell which may be fabricated using the manufacturing methods described above. All of the above variations described in the context of single junction GaAs solar cells are equally applicable to multi-junction solar cells, and may be specifically applicable in the context of both emitter first and emitter last front contact solar cell architectures (approaches).

In operation, the disclosed subject matter provides various structures and methods of manufacturing large area (for example having the size range of approximately 125 mm×125 mm to 210 mm×210 mm) low cost thin (for example having a thickness in the range of approximately 0.1 μm to 10 μm and an active semiconductor layer thickness in the range of approximately 0.1 μm to 2 μm) high efficiency solar cells using direct bandgap crystalline semiconductor absorber enabled by a silicon-based template and release/lift-off platform technology. This includes but is not limited to, single junction solar cells using III-V semiconductors such as GaAs, as well as a myriad combination of different III-V compound semiconductor materials to create very high efficiency multi-junction, tandem solar cells. The idea leverages and builds upon a robust, low-cost foundation platform technology that has been successfully demonstrated to for forming thin crystalline.

Key features and attributes of various embodiments disclosed herein include the capability to make solar cell efficiencies higher than the limits of crystalline silicon (for example efficiencies greater than 28%) on a very large area solar cell (in some instances much larger than conventional compound semiconductor based solar cells) with very high yield and low cost. Solar cell size may range from approximately 100 mm by 100 mm to 210 mm by 210 mm or larger if required; and the efficiencies may be approximately 28% (for example with a GaAs single junction cell) and may go up to 43% (for example with a triple junction tandem cell configuration). Further, because only thin layers ranging from 0.5 um to 5 um thickness (and thus exploiting the high absorption of direct bandgap materials) are used, material consumption and cost is substantially reduced making this very high efficiency solar cell technology cost effective and viable for terrestrial application and presenting an opportunity to reduce the LCOE metric to below that of fossil fuels.

It will be apparent to those skilled in the art that various modifications and variations may be made in the above disclosure and aspects of the disclosure without departing from the scope or intent of the disclosure. Other embodiments of the disclosure will be apparent to those skilled in the art from consideration of the specification and practice of the disclosure disclosed herein. It is intended that the specification and examples be considered as exemplary only. Accordingly, the scope of the present disclosure should be limited only by the attached claims.

What is claimed is:

1. A method for fabrication of a thin-film compound semiconductor substrate by releasing it from a Si semiconductor template through the use of a sacrificial porous semiconductor seed and release layer, the method comprising:
forming a porous Si layer on a Si semiconductor template, said porous Si layer substantially conformal to said semiconductor template;
forming a Ge layer on said porous Si layer, said Ge layer substantially conformal to said porous Si layer;
forming a thin GaAs layer on said Ge layer, said GaAs layer substantially conformal to said Ge layer; and
releasing said thin GaAs layer from said template along said porous Si layer.

2. The method of claim 1, wherein said step forming a porous Si layer further comprises forming a porous Si layer comprising at least two different porosities.
